(19) United States
(12) Patent Application Publication
(10) Pub. No.: US 2025/0350859 A1
(43) Pub. Date: Nov. 13, 2025

(54) SOLID-STATE IMAGING DEVICE

(71) Applicant: SONY SEMICONDUCTOR SOLUTIONS CORPORATION, KANAGAWA (JP)

(72) Inventor: SHINICHI MIYAKE, KANAGAWA (JP)

(21) Appl. No.: 18/868,769

(22) PCT Filed: May 22, 2023
(86) PCT No.: PCT/JP2023/018939

§ 371 Date: Nov. 24, 2024

(30) Foreign Application Priority Data
May 31, 2022 (JP) 2022-089162

(51) Int. Cl. H04N 25/57; H01L 23/522; H04N 25/771; H04N 25/78; H04N 25/79; H10F 39/00

(52) U.S. Cl. CPC H04N 25/57; H04N 25/771; H04N 25/78; H04N 25/79; H01L 23/5223; H10F 39/809; H10F 39/811

(57) ABSTRACT

[Problem] To expand a dynamic range and output high quality image data with low power consumption. [Solution] A solid-state imaging device includes: a photoelectric conversion element; a charge-voltage conversion unit that converts charge photoelectrically converted by the photoelectric conversion element into a voltage; a capacitor that is connected to the charge-voltage conversion unit and adjusts a voltage level of the charge-voltage conversion unit; a first semiconductor layer in which the photoelectric conversion element and the capacitor are arranged; a signal line that transmits a pixel signal according to the voltage level of the charge-voltage conversion unit; and a comparator that is arranged on the signal line and compares the pixel signal with a predetermined reference signal.

### TECHNICAL FIELD

The present disclosure relates to a solid-state imaging device.

### BACKGROUND ART

A solid-state imaging device is equipped with an analog to digital converter (ADC) that digitally converts an analog pixel signal photoelectrically converted by a pixel. For example, a single-slope ADC generally includes a comparator that compares an analog signal of a pixel with a reference signal, and a counter that measures a time until the reference signal substantially matches the analog signal.

The single-slope ADC has an advantage that the structure is simple and the area can be saved. For this reason, in a solid-state imaging device using a single-slope ADC, a comparator capable of accurately comparing a pixel signal with a reference signal is required (see, for example, Patent Document 1).

### CITATION LIST

### Patent Document

Patent Document 1: WO 2020/170518 A1

### SUMMARY OF THE INVENTION

### Problems to Be Solved by the Invention

In a solid-state imaging device using a single-slope ADC, a pixel signal transferred from each pixel to a signal line is generally compared with a reference signal. For this reason, the signal line is provided with a comparator and a load current source. The comparator includes a transistor, and for example, a pixel signal is input to the source of the transistor, and a reference signal is input to the gate of the transistor. As a result, the transistor is turned on or off by a difference in signal level between the pixel signal and the reference signal, whereby comparison operation is performed.

However, when the above-described transistor is connected on the signal line, a potential difference is generated between the source and the drain of the transistor, and this potential difference narrows a dynamic range of the pixel signal on the signal line. More specifically, a voltage of the signal line on the high luminance side cannot be reduced due to the potential difference between the source and the drain of the transistor described above, and the dynamic range is narrowed.

The present disclosure has been made in view of the above-described problem, and provides a solid-state imaging device capable of expanding a dynamic range as compared with a conventional solid-state imaging device and outputting high-quality image data with low power consumption.

### Solutions to Problems

In order to solve the problem described above, according to the present disclosure, there is provided a solid-state imaging device including: a photoelectric conversion element; a charge-voltage conversion unit that converts charge photoelectrically converted by the photoelectric conversion element into a voltage; a capacitor that is connected to the charge-voltage conversion unit and adjusts a voltage level of the charge-voltage conversion unit; a first semiconductor layer in which at least one of the photoelectric conversion element or the capacitor is arranged; a signal line that transmits a pixel signal according to the voltage level of the charge-voltage conversion unit; and a comparator that is arranged on the signal line and compares the pixel signal with a predetermined reference signal.

There may be further provided a reference signal generation unit that generates a reference signal whose voltage level is changeable with time, and the capacitor may adjust the voltage level of the charge-voltage conversion unit on the basis of the reference signal.

A switching element may be further included that is connected to the capacitor and increases or decreases a voltage level of the capacitor while the switching element continues to be turned on or off.

The capacitor may include a first electrode connected to the charge-voltage conversion unit, a second electrode to which the reference signal is applied, and an insulator layer arranged between the first electrode and the second electrode.

The first electrode and the second electrode may be arranged to be separated from each other in a plane direction of a wiring layer connected to the charge-voltage conversion unit.

The first electrode and the second electrode may be arranged to be separated from each other in a stacking direction of a wiring layer connected to the charge-voltage conversion unit.

There may be provided: a first wiring layer and a second wiring layer stacked on the first semiconductor layer; and an insulator layer arranged between the first wiring layer and the second wiring layer, and the capacitor may include the first wiring layer, the second wiring layer, and the insulator layer.

Pixels including the photoelectric conversion element, the capacitor, and a pixel circuit may be arranged in the first semiconductor layer.

The capacitor and the charge-voltage conversion unit may be provided for each of the pixels.

The capacitor and the charge-voltage conversion unit may be shared by a plurality of the pixels.

There may be provided: a first chip including the first semiconductor layer; and a second chip stacked on the first chip and including a second semiconductor layer, and the comparator may be provided in the second semiconductor layer.

There may be provided: a first chip including the first semiconductor layer; and a second chip stacked on the first chip and including a second semiconductor layer, and the comparator may be provided in the second semiconductor layer, and the capacitor may be arranged at a bonding portion between the first chip and the second chip.

The bonding portion may include: a first conductive layer; a second conductive layer; and an insulator layer arranged between the first conductive layer and the second conductive layer.

The first conductive layer, the insulator layer, and the second conductive layer may be arranged along a stacking direction of the first chip and the second chip.

There may be provided a pixel circuit including at least one transistor that performs control to read out charge photoelectrically converted by the photoelectric conversion element, and the capacitor may include: a first electrode arranged at a layer height identical to a layer height of a gate electrode of the transistor; a second electrode arranged at a layer height identical to a layer height of a source region and a drain region of the transistor; and an insulator layer arranged at a layer height identical to a layer height of a gate insulating film of the transistor.

There may be provided a second semiconductor layer that is stacked on the first semiconductor layer and in which the capacitor and at least one transistor that performs control to read out charge photoelectrically converted by the photoelectric conversion element are arranged, and the capacitor may include: a first electrode arranged at a layer height identical to a layer height of a gate electrode of the transistor; a second electrode arranged at a layer height identical to a layer height of a source region and a drain region of the transistor; and an insulator layer arranged at a layer height identical to a layer height of a gate insulating film of the transistor.

There may be provided a well region in which at least a part of the capacitor is arranged, and a flat band voltage may be controlled by adjusting an amount of impurities of at least a part in the well region.

There may be provided: a first chip including the first semiconductor layer; and a second chip stacked on the first chip and including a third semiconductor layer, and the comparator may be provided in the third semiconductor layer.

### BRIEF DESCRIPTION OF DRAWINGS

FIG. 1 is a block diagram schematically illustrating a solid-state imaging device according to the present disclosure.

FIG. 2 is a circuit diagram illustrating an example of a circuit configuration of a pixel.

FIG. 3A is a perspective view schematically illustrating a flat-type chip structure of the solid-state imaging device.

FIG. 3B is a perspective view schematically illustrating a stacked-type chip structure of the solid-state imaging device.

FIG. 4 is a block diagram illustrating an example of a basic configuration of an analog-digital conversion unit and a peripheral portion.

FIG. 5 is a circuit diagram illustrating an example of a comparator and a peripheral portion in the basic configuration.

FIG. 6 is a waveform diagram illustrating an input signal input to a comparator in the basic configuration.

FIG. 7 is a block diagram of an analog-digital conversion unit and a peripheral portion thereof in a first embodiment of the present disclosure.

FIG. 8 is a circuit diagram illustrating an example of a comparator and a peripheral portion thereof in the first embodiment of the present disclosure.

FIG. 9 is a timing chart for explaining operation of the solid-state imaging device in the first embodiment of the present disclosure.

FIG. 10 is a waveform diagram illustrating an input signal input to the comparator in the first embodiment of the present disclosure.

FIG. 11 is a circuit diagram illustrating an example in which a part of a pixel circuit is shared by a plurality of pixels.

FIG. 12 is a circuit diagram illustrating an example of the comparator and the peripheral portion thereof in a case where a reference signal is separated into a first reference signal and a second reference signal.

FIG. 13 is an operation timing chart diagram in a case where the reference signal is separated into the first reference signal and the second reference signal and supplied to each of the pixel and the comparator.

FIG. 14 is a circuit diagram of the pixel in which a reference signal generation unit is provided.

FIG. 15 is a cross-sectional view of the solid-state imaging device of a stacked-type in the first embodiment of the present disclosure.

FIG. 16A is a schematic diagram illustrating a cross-sectional structure of a capacitor in which electrodes are arranged to face each other in a stacking direction within a wiring layer region.

FIG. 16B is a schematic diagram illustrating a cross-sectional structure of the capacitor in which electrodes are arranged along one wiring layer.

FIG. 17 is a schematic diagram illustrating a cross-sectional structure of the capacitor in the pixel in a second embodiment of the present disclosure.

FIG. 18 is a schematic diagram illustrating a cross-sectional structure of the capacitor in the pixel in a third embodiment of the present disclosure.

FIG. 19 is a cross-sectional view of the pixel in a fourth embodiment of the present disclosure.

FIG. 20 is a cross-sectional view of the solid-state imaging device of a stacked-type in a fifth embodiment of the present disclosure.

FIG. 21 is a cross-sectional view of the pixel in the fifth embodiment of the present disclosure.

FIG. 22 is a circuit diagram illustrating an example of the comparator and the peripheral portion thereof in the fifth embodiment of the present disclosure.

FIG. 23 is a block diagram illustrating an example of a schematic configuration of a vehicle control system.

FIG. 24 is an explanatory diagram illustrating an example of installation positions of an outside-vehicle information detecting section and an imaging section.

### MODE FOR CARRYING OUT THE INVENTION

Hereinafter, embodiments of a solid-state imaging device will be described with reference to the drawings. Although main components of the solid-state imaging device will be mainly described below, the solid-state imaging device can have components and functions that are not illustrated or described. The following description does not exclude components and functions that are not illustrated or described.

### Schematic Configuration of Solid-State Imaging Device

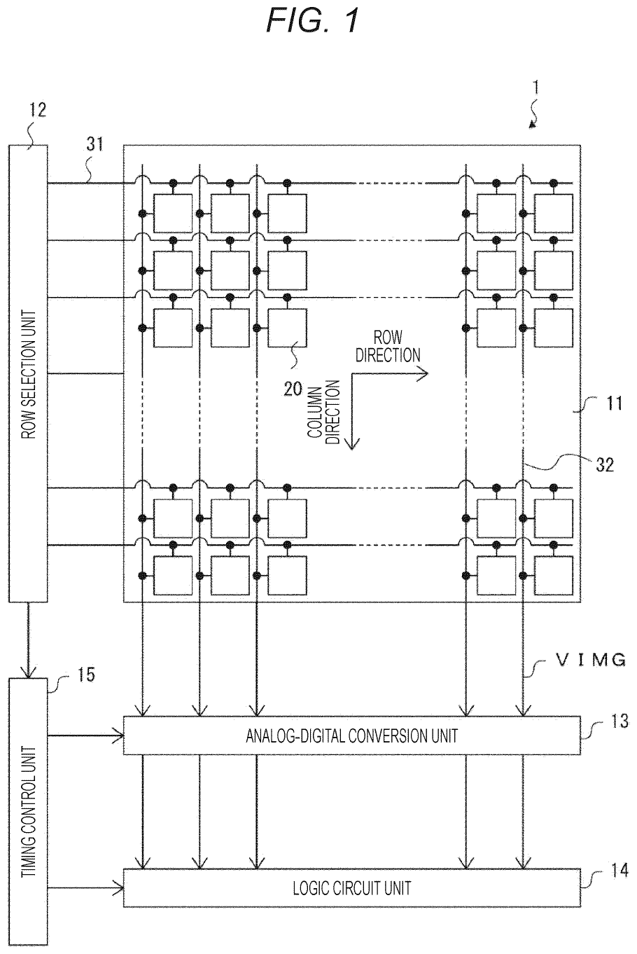

FIG. 1 is a block diagram schematically illustrating a solid-state imaging device 1 according to the present disclosure.

The solid-state imaging device 1 according to the present disclosure includes a pixel array unit 11, a row selection unit 12, an analog-digital conversion unit 13, a logic circuit unit 14, and a timing control unit 15.

The pixel array unit 11 has a configuration in which a plurality of pixels 20 is two-dimensionally arranged in a matrix. Here, a column direction is a direction in which a plurality of row selection lines 31 is arranged, and is a direction in which each of signal lines 32 extends. A row direction is a direction in which the plurality of signal lines 32 is arranged, and is a direction in which each row selection line 31 extends. In the present specification, the pixels 20 of one row arranged in the row direction are referred to as a pixel row, and the pixels 20 of one column arranged in the column direction are referred to as a pixel column. In the pixel array unit 11, the row selection line 31 is arranged for each of pixel rows. One end of the row selection line 31 is connected to an output end corresponding to one of the rows of the row selection unit 12. Furthermore, the signal lines 32 are arranged for respective pixel columns. Each signal line 32 transmits a pixel signal VIMG output from the pixels 20 in a corresponding pixel column. The pixel signal VIMG transmitted by each signal line 32 is input to the analog-digital conversion unit 13. The pixel 20 includes a photoelectric conversion element and a pixel circuit (not illustrated in FIG. 1). The photoelectric conversion element receives light from a subject and generates charge according to an amount of received light. The generated charge is converted into the pixel signal VIMG by the pixel circuit. The pixel signal VIMG is a voltage signal corresponding to the charge generated by the photoelectric conversion element.

Although not illustrated, the row selection unit 12 includes a shift register, an address decoder, and the like. As described above, the plurality of row selection lines 31 is connected to the row selection unit 12. The row selection unit 12 sequentially drives the plurality of row selection lines 31 to sequentially select corresponding pixel rows in the pixel array unit 11.

The row selection unit 12 performs two types of scanning, reading and sweeping, on the plurality of pixel rows. In the reading, each pixel 20 in the selected pixel row transmits the charge corresponding to the amount of received light as the analog pixel signal VIMG to the analog-digital conversion unit 13 through a corresponding one of the signal lines 32. In the sweeping, each pixel 20 in the selected pixel row performs reset processing for sweeping unnecessary charge from the pixel circuit and newly starting exposure.

The analog-digital conversion unit 13 performs conversion into a digital pixel signal on the basis of a result of comparison between a reference voltage generated by digital-to-analog (DA) conversion and the pixel signal VIMG transmitted via the signal line 32. The digital pixel signal is transmitted to the logic circuit unit 14.

The logic circuit unit 14 performs predetermined signal processing on the digital pixel signal to generate image data. Examples of the signal processing include correction of a vertical line defect or a point defect, clamping of a signal, parallel-to-serial conversion, compression, encoding, addition, averaging, intermittent operation, and the like. The image data is output to a subsequent device as an output signal from the solid-state imaging device 1.

The timing control unit 15 generates various timing signals and a clock signal CLK on the basis of a synchronization signal provided from the outside. Then, the timing control unit 15 controls timings of the row selection unit 12, the analog-digital conversion unit 13, and the logic circuit unit 14 on the basis of the generated signals.

### Schematic Configuration of Pixel

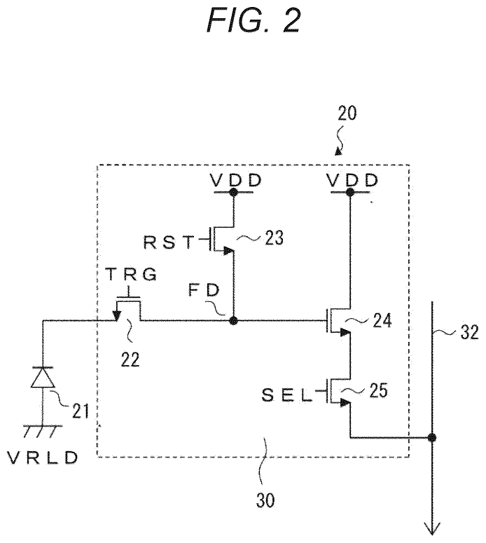

FIG. 2 is a circuit diagram illustrating an example of a circuit configuration of the pixel 20. The pixel 20 in FIG. 2 includes a photoelectric conversion element 21 and a pixel circuit 30. The pixel circuit 30 includes a transfer transistor 22, a reset transistor 23, an amplification transistor 24, and a selection transistor 25. A connection node to which each of the transfer transistor 22, the reset transistor 23, and the amplification transistor 24 is connected is a floating diffusion (floating diffusion region/impurity diffusion region). In the present specification, the floating diffusion is referred to as a charge-voltage conversion unit FD. The pixel signal VIMG output from the pixel 20 is input to the analog-digital conversion unit 13 described above via the signal line 32.

In the present specification, an example will be described in which four transistors of the transfer transistor 22, the reset transistor 23, the amplification transistor 24, and the selection transistor 25 in the pixel circuit 30 are, for example, N channel Metal-Oxide-Semiconductor (NMOS) transistors. However, conductivity types of the four transistors exemplified here are any conductivity types, and all the transistors may be constituted by P channel Metal-Oxide Semiconductor (PMOS) transistors, or NMOS transistors and PMOS transistors may be mixed. In the present specification, an example will be described in which the pixel circuit 30 has a 4-transistor (Tr) configuration including four transistors, but the present invention is not limited thereto. For example, a 3-Tr configuration may be employed in which the selection transistor 25 is omitted and the amplification transistor 24 has a function of the selection transistor 25, or a configuration of 5-Tr or more may be employed in which the number of transistors is increased, as necessary.

Each of the transfer transistor 22, the reset transistor 23, and the selection transistor 25 is used for scanning control of the pixel 20, and is turned on or off by a signal provided from the row selection unit 12 described above. The gates of the three transistors used for scanning control of the pixel 20 are connected to the row selection unit 12 by the row selection line 31, but the connections are not illustrated in FIG. 2.

When the pixel 20 receives light, the photoelectric conversion element 21 accumulates photocharge according to an amount of incident light. As the photoelectric conversion element 21, for example, a photodiode is used. In the photoelectric conversion element 21, one electrode of a cathode electrode and an anode electrode is connected to the transfer transistor 22. The other electrode is connected to a reference potential node VRLD such as ground. Hereinafter, in the present specification, an example will be described in which the cathode electrode is connected to the transfer transistor 22.

The transfer transistor 22 is used to switch transfer of the photocharge. In the transfer transistor 22, the source is connected to the photoelectric conversion element 21, and the drain is connected to the charge-voltage conversion unit FD. A transfer signal TRG whose high level (for example, a high-potential-side power supply VDD level to be described later) is active is provided to the gate from the row selection unit 12, whereby the transfer transistor 22 is turned. As a result, the photocharge accumulated in the photoelectric conversion element 21 is transferred to the charge-voltage conversion unit FD.

The reset transistor 23 is used to reset an amount of photocharge in the pixel 20. In the reset transistor 23, the source is connected to the charge-voltage conversion unit FD, and the drain is connected to a node of the high-potential-side power supply VDD. A reset signal RST whose high level is active is provided to the gate from the row selection unit 12, whereby the reset transistor 23 is turned on. As a result, the charge of the charge-voltage conversion unit FD is discharged to the node of the high-potential-side power supply VDD, whereby the charge-voltage conversion unit FD is reset.

The charge-voltage conversion unit FD converts the photocharge transferred from the photoelectric conversion element 21 into a voltage.

The amplification transistor 24 is used as an input section of a source follower for a signal from the charge-voltage conversion unit FD. In the amplification transistor 24, the gate is connected to the charge-voltage conversion unit FD, the drain is connected to the node of the high-potential-side power supply VDD, and the source is connected to the selection transistor 25. The amplification transistor 24 transmits a signal of the photoelectric conversion element 21 by varying a current from the high-potential-side power supply VDD flowing through the selection transistor 25 on the basis of the voltage of the charge-voltage conversion unit FD.

The selection transistor 25 is used to switch signal transmission from the pixel 20. In the selection transistor 25, the drain is connected to the amplification transistor 24, and the source is connected to the signal line 32. A selection signal SEL whose high level is active is provided to the gate from the row selection unit 12, whereby the selection transistor 25 is turned on. As a result, a signal output from the drain of the amplification transistor 24 is transmitted as the pixel signal VIMG to the analog-digital conversion unit 13 via the signal line 32. The pixel signals VIMG output from the selection transistors 25 in the respective pixels 20 belonging to the pixel row connected to the row selection line 31 selected by the row selection unit 12 in the pixel array unit 11 in FIG. 1 are transmitted to the analog-digital conversion unit 13 at the same timing via the plurality of signal lines 32.

As described above, a potential level of the charge-voltage conversion unit FD in the pixel 20 changes between a state in which the photocharge is transferred and a state in which the photocharge is reset. The former state is a potential level of the pixel signal VIMG based on photoelectric conversion. The latter state is a potential level (also referred to as a reset level) obtained by resetting the pixel signal VIMG. The row selection unit 12 performs operation of selecting the reset level of the pixel signal VIMG of each pixel 20 for each pixel row, and operation of selecting the pixel signal VIMG photoelectrically converted in each pixel 20 for each pixel row.

### Schematic Configuration of Semiconductor Chip

As a semiconductor chip structure of the solid-state imaging device 1 having the configuration described above, a flat-type semiconductor chip structure and a stacked-type semiconductor chip structure can be exemplified. Furthermore, regarding a pixel structure, when a substrate surface on a side on which a wiring layer is formed is defined as a front surface (front), a back-illuminated pixel structure can be employed that receives light emitted from a back surface side opposite to the front surface, or a front-illuminated pixel structure can be employed that receives light emitted from a front surface side.

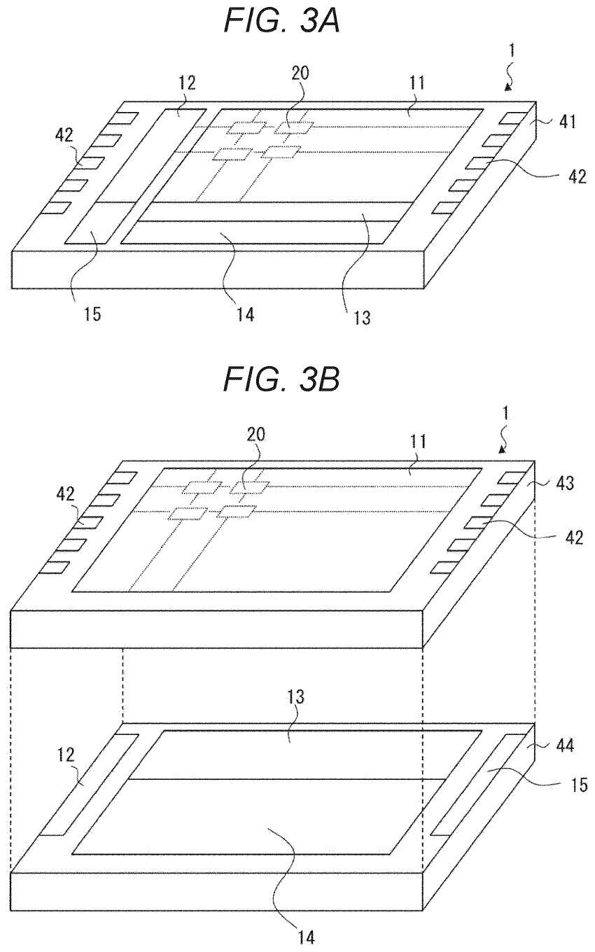

FIG. 3A is a perspective view schematically illustrating a flat-type chip structure of the solid-state imaging device 1. As illustrated in FIG. 3A, the flat-type semiconductor chip structure has a structure in which components of a peripheral circuit portion of the pixel array unit 11 are arranged on a semiconductor chip 41 having the pixel array unit 11 in which the pixels 20 are arranged in a matrix. Specifically, the row selection unit 12, the analog-digital conversion unit 13, the logic circuit unit 14, the timing control unit 15, and the like are arranged on the same semiconductor chip 41 on which the pixel array unit 11 is arranged. Note that, for example, pads 42 for external connection and power supply are provided at both left and right ends of the semiconductor chip 41.

FIG. 3B is an exploded perspective view schematically illustrating a stacked-type semiconductor chip structure of the solid-state imaging device 1. As illustrated in FIG. 3B, the stacked-type semiconductor chip structure, a so-called stacked structure, has a structure in which at least two semiconductor chips of a semiconductor chip of the first layer and a semiconductor chip of the second layer are stacked.

In the stacked-type semiconductor chip structure, the semiconductor chip of the first layer arranged on the light incident side is a so-called CMOS image sensor (CIS) chip 43 including the pixel array unit 11 in which the pixels 20 including the photoelectric conversion elements 21 are two-dimensionally arranged in a matrix. For example, the pads 42 for external connection and power supply are provided at both left and right ends of the CIS chip 43 of the first layer.

The semiconductor chip of the second layer is a so-called logic chip 44 in which the peripheral circuit portion of the pixel array unit 11, that is, the row selection unit 12, the analog-digital conversion unit 13, the logic circuit unit 14, the timing control unit 15, and the like are arranged.

The pixel array unit 11 on the CIS chip 43 of the first layer and the peripheral circuit portion on the logic chip 44 of the second layer are connected together by Cu—Cu bonding that directly bonds Cu electrodes together, or the like, and perform transmission of various signals. Note that the CIS chip 43 and the logic chip 44 may be connected together by a via, a bump, or the like in addition to Cu—Cu bonding.

According to the flat-type semiconductor chip structure, by integrating the pixel 20 portion and the circuit portion of the solid-state imaging device 1 into one semiconductor chip 41, it is possible to simplify a manufacturing process. On the other hand, according to the stacked-type semiconductor chip structure, by dividing the pixel 20 portion and the circuit portion into the CIS chip 43 and the logic chip 44, respectively, it is possible to make manufacturing processes different for respective chips. That is, a process suitable for fabricating the pixel array can be applied to the CIS chip 43 of the first layer, and a process suitable for fabricating the circuit portion can be applied to the logic chip 44 of the second layer. As a result, process optimization can be made in manufacturing the solid-state imaging device 1. In particular, an advanced process can be applied when the circuit portion is fabricated.

Note that arrangements of the pixel array unit 11, the row selection unit 12, the analog-digital conversion unit 13, the logic circuit unit 14, and the timing control unit 15 illustrated in FIGS. 3A and 3B are examples, and are not limited to the arrangement examples.

### Basic Configuration of Analog-Digital Conversion Unit and Peripheral Portion Thereof

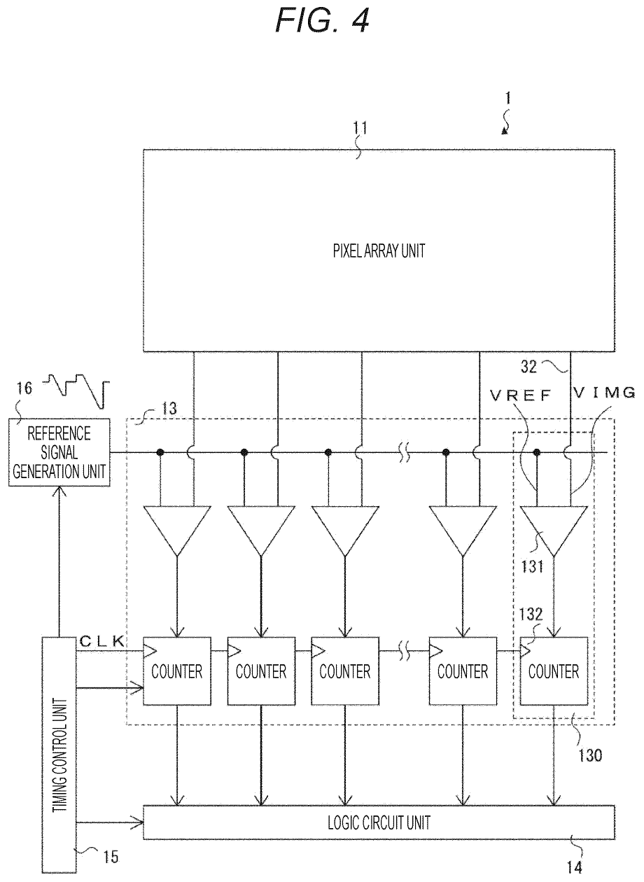

FIG. 4 is a block diagram illustrating an example of a basic configuration of the analog-digital conversion unit 13 and a peripheral portion thereof. In the solid-state imaging device 1, the analog-digital conversion unit 13 includes a plurality of analog-digital converters provided corresponding to respective pixel columns of the pixel array unit 11.

Hereinafter, a description will be given of a single analog-digital converter (for example, an analog-digital converter 130 of the n-th column) in the analog-digital conversion unit 13. The analog-digital converter 130 is used to convert the analog pixel signal VIMG into a digital pixel signal. The analog-digital converter 130 receives as inputs the pixel signal VIMG from the pixel array unit 11, the clock signal CLK from the timing control unit 15, and a reference signal VREF from a reference signal generation unit 16. Moreover, the analog-digital converter 130 outputs a digital pixel signal obtained by converting the pixel signal VIMG to the logic circuit unit 14.

In the present specification, a single-slope type is used as the analog-digital converter 130. In this case, one analog-digital converter 130 includes a comparator 131 and a counter 132.

The comparator 131 is used to compare the pixel signal VIMG with the reference signal VREF. The comparator 131 compares the pixel signal VIMG transmitted via the signal line 32 with the reference signal VREF from the reference signal generation unit 16. An output node that outputs a comparison result by the comparator 131 is connected to the counter 132. The comparator 131 compares the pixel signal VIMG with the reference signal VREF, and for example, when the reference signal VREF is greater than the pixel signal VIMG, the output is in a first state (for example, high level). Furthermore, when the reference signal VREF is less than or equal to the pixel signal VIMG, the output is in a second state (for example, low level). As a result, the comparator 131 inputs a pulse signal having a pulse width corresponding to a signal level of the pixel signal VIMG, specifically, magnitude of the signal level, to the counter 132 as a comparison result.

The counter 132 is used to measure a period until an output signal of the comparator 131 is inverted and output a digital pixel signal corresponding to a length of the period. The output signal of the comparator 131 and an output signal of the timing control unit 15 are input to the counter 132. The digital pixel signal output from the counter 132 is input to the logic circuit unit 14. The counter 132 performs counting operation in synchronization with the clock signal CLK from the timing control unit 15 and measures a period of the pulse width of the output signal of the comparator 131. For example, a period is measured from when the pixel signal VIMG becomes lower than the reference signal VREF to when the pixel signal VIMG becomes higher than the reference signal VREF. The counter 132 generates a count value by the counting operation and outputs the count value as a digital pixel signal to the logic circuit unit 14.

According to the analog-digital converter 130 described above, the input analog pixel signal VIMG can be converted into a digital pixel signal corresponding to a period until a magnitude relationship between the pixel signal VIMG and the reference signal VREF changes. Note that, in the above example, a configuration has been exemplified in which the analog-digital converter 130 is arranged on a one-to-one basis with respect to the pixel column of the pixel array unit 11, but a configuration may be employed in which one analog-digital converter 130 may be arranged with respect to a plurality of pixel columns.

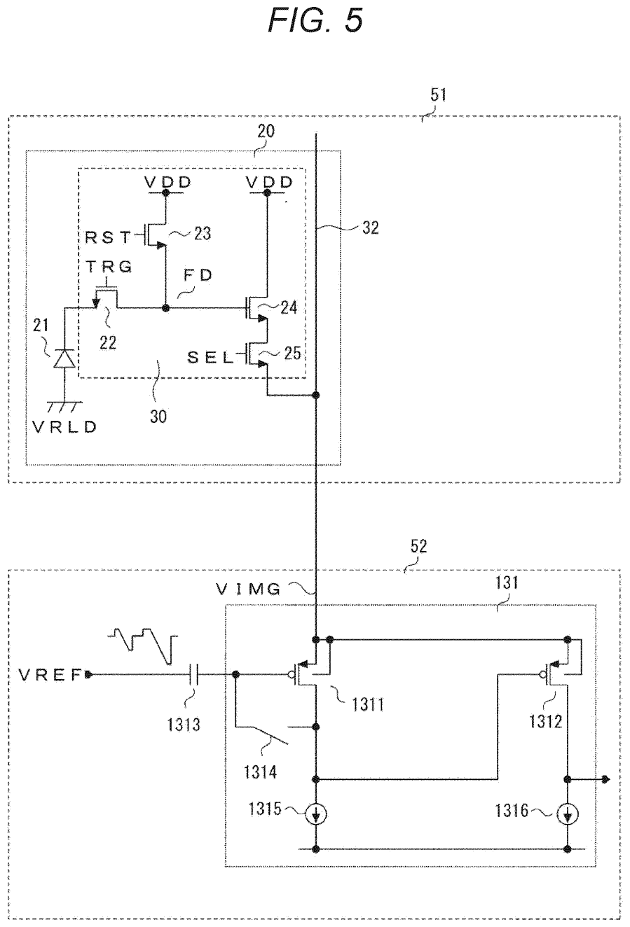

FIG. 5 is a circuit diagram illustrating an example of the comparator 131 and a peripheral portion thereof in the basic configuration. Here, in order to simplify the drawing, a circuit configuration for one pixel column is illustrated. The comparator 131 in FIG. 5 includes an input transistor 1311, an output transistor 1312, a capacitor 1313, an auto-zero switch 1314, an input-side load current source 1315, and an output-side load current source 1316. The comparator 131 is connected to the pixel column via the signal line 32. Furthermore, the comparator 131 is connected to the reference signal generation unit 16 and the counter 132 as described above.

Here, the pixel 20 is arranged in a first semiconductor layer 51, and the comparator 131, the reference signal generation unit 16, and the counter 132 are arranged in a second semiconductor layer 52. Furthermore, in the case of the stacked-type semiconductor chip structure as illustrated in FIG. 3B, the CIS chip 43 includes the first semiconductor layer 51, and the logic chip 44 includes the second semiconductor layer 52. Note that each of the CIS chip 43 and the logic chip 44 may include a plurality of semiconductor layers.

The reference signal generation unit 16 supplies the reference signal VREF having a ramp wave shape to the comparator 131 in synchronization with the clock signal CLK provided from the timing control unit 15. Here, the ramp wave is a signal whose potential level changes with time, and is typically a sawtooth wave. A signal waveform of the reference signal VREF is not always sawtooth. Furthermore, the reference signal VREF may include a ramp wave for the reset level of the pixel signal VIMG or may include a ramp wave for the pixel signal VIMG depending on timing.

The capacitor 1313 is used to transmit the reference signal VREF to the comparator 131. The capacitor 1313 is connected between an output node of the reference signal generation unit 16 and the gate of the input transistor 1311. The capacitor 1313 becomes an input capacitance with respect to the reference signal VREF, and transmits the reference signal VREF to the input transistor 1311 in a state of absorbing an offset.

The input transistor 1311 is used to compare the reference signal VREF with the pixel signal VIMG. As the input transistor 1311, for example, a P channel Metal-Oxide-Semiconductor (PMOS) transistor is used. The source of the input transistor 1311 is connected to one end of the signal line 32, and the drain is connected to one end of the input-side load current source 1315 and the output transistor 1312. Furthermore, the gate of the input transistor 1311 is connected to the capacitor 1313. To the input transistor 1311, the pixel signal VIMG is input to the source side, and the reference signal VREF is input to the gate. As a result, the input transistor 1311 compares a signal level of the pixel signal VIMG with a signal level of the reference signal VREF, and controls a drain voltage according to a comparison result. More specifically, the drain voltage of the input transistor 1311 becomes high in a case where the signal level of the pixel signal VIMG is smaller than the signal level of the reference signal VREF, and becomes low when the signal level of the pixel signal VIMG matches the signal level of the reference signal VREF.

The auto-zero switch 1314 is used for initialization operation of the input transistor 1311. The auto-zero switch 1314 is connected between the gate and the drain of the input transistor 1311. The auto-zero switch 1314 performs on (close)/off (open) control by a drive signal. The auto-zero switch 1314 is turned on to perform auto-zeroing (initialization operation) for short-circuiting between the gate and the drain of the input transistor 1311. The auto-zero switch 1314 can be configured using a PMOS transistor or an NMOS transistor. By providing the auto-zero switch 1314, it is possible to accumulate charge based on the drain voltage of the input transistor 1311 in the capacitor 1313, and perform offset adjustment of the input transistor 1311.

One end of the input-side load current source 1315 is connected to one end of the input transistor 1311 and the signal line 32, and the other end of the input-side load current source 1315 is connected to a low-potential-side power supply (for example, ground). The input-side load current source 1315 supplies a constant current to a series connection circuit of the input transistor 1311 and the signal line 32.

One end of the output-side load current source 1316 is connected to one end of the input transistor 1311 and the signal line 32, and the other end of the output-side load current source 1316 is connected to a low-potential-side power supply, for example, ground). The output-side load current source 1316 supplies a constant current to a series connection circuit of the output transistor 1312 and the signal line 32.

The output transistor 1312 is used to output a result of comparison between the reference signal VREF and the pixel signal VIMG. The output transistor 1312 is, for example, a PMOS transistor. In the output transistor 1312, the source is connected to one end of the signal line 32, and the gate is connected to the drain of the input transistor 1311.

The output transistor 1312 outputs, from the drain, a signal indicating whether or not a voltage difference between the pixel signal VIMG input to the source and the drain voltage of the input transistor 1311 input to the gate exceeds a predetermined threshold voltage. The signal is a signal indicating the result of comparison between the pixel signal VIMG and the reference signal VREF, and is sent to the counter 132. As described above, in a case where the signal level of the pixel signal VIMG is lower than the signal level of the reference signal VREF, the input transistor 1311 is in an OFF state, and the drain voltage (gate voltage of the output transistor 1312) thereof becomes high, so that a drain voltage of the output transistor 1312 becomes high. On the other hand, when the signal level of the pixel signal VIMG matches the signal level of the reference signal VREF, the drain voltage of the input transistor 1311 (the gate voltage of the output transistor 1312) becomes low, and the drain voltage of the output transistor 1312 becomes low.

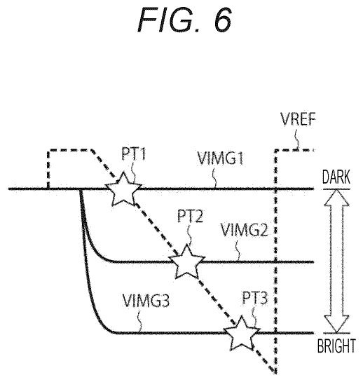

FIG. 6 is a waveform diagram illustrating an input signal input to the comparator 131 in the basic configuration in FIG. 5. As described above, the pixel signal VIMG and the reference signal VREF are input to the comparator 131. Note that the signal level of the pixel signal VIMG changes depending on an amount of light received by the pixel 20. Three signal levels of a pixel signal VIMG1, a pixel signal VIMG2, and a pixel signal VIMG3 are considered in ascending order of the amount of received light. FIG. 6 illustrates the reference signal VREF and the pixel signals VIMG1, VIMG2, and VIMG3. Furthermore, the reference signal VREF intersects the pixel signals VIMG1, VIMG2, and VIMG3 at timings PT1, PT2, and PT3, respectively.

The signal level of the reference signal VREF changes with time. On the other hand, the signal level of the pixel signal VIMG decreases when the pixel 20 receives light. A degree of decrease in the signal level of the pixel signal VIMG varies depending on the amount of light received by the pixel 20. For example, the degree of decrease in the signal level of the pixel signal VIMG becomes larger as light with higher luminance is received.

A timing at which the comparator 131 detects a match varies depending on the signal level of the pixel signal. FIG. 6 illustrates the timings PT1, PT2, and PT3 at which three pixel signals VIMG1, VIMG2, and VIMG3 having different signal levels intersect with the reference signal VREF.

For example, the pixel signal VIMG3 having the largest amount of received light intersects with the reference signal VREF at the timing PT3 at which the reference signal VREF is lower than the others. As described above, in the basic configuration in FIG. 5, the signal level of the pixel signal VIMG greatly changes depending on the amount of received light, and it is necessary to greatly change the signal level of the reference signal VREF accordingly.

The basic configuration has an advantage that it is possible to reduce the size and power consumption of the solid-state imaging device 1 in that the input transistor 1311 in the comparator 131 is on the signal line 32, as compared with a configuration in which the comparator 131 is not on the signal line 32. However, as a potential difference is generated between the source and the drain of the input transistor 1311, a dynamic range of the pixel signal VIMG on the signal line 32 decreases. In particular, accuracy of comparing the pixel signal VIMG on the high luminance side with the reference signal VREF decreases, which causes a decrease in image quality. In each of embodiments described below, this problem can be solved.

### First Embodiment of Present Disclosure

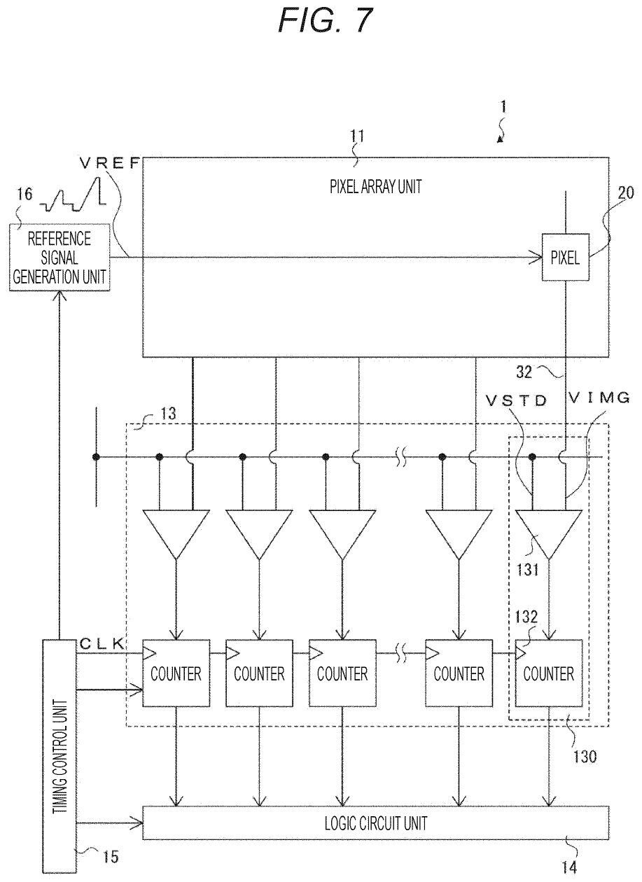

FIG. 7 is a block diagram of the analog-digital conversion unit 13 and the peripheral portion thereof in a first embodiment of the present disclosure. The comparator 131 in FIG. 4 compares the pixel signal VIMG with the reference signal VREF, whereas the comparator 131 in FIG. 7 compares the pixel signal VIMG with a reference voltage signal VSTD. The reference voltage signal VSTD is a signal having a fixed potential level, and is, for example, a ground voltage level. In FIG. 7, the reference signal VREF similar to that in FIG. 4 is supplied not to the comparator 131 but to the pixel 20.

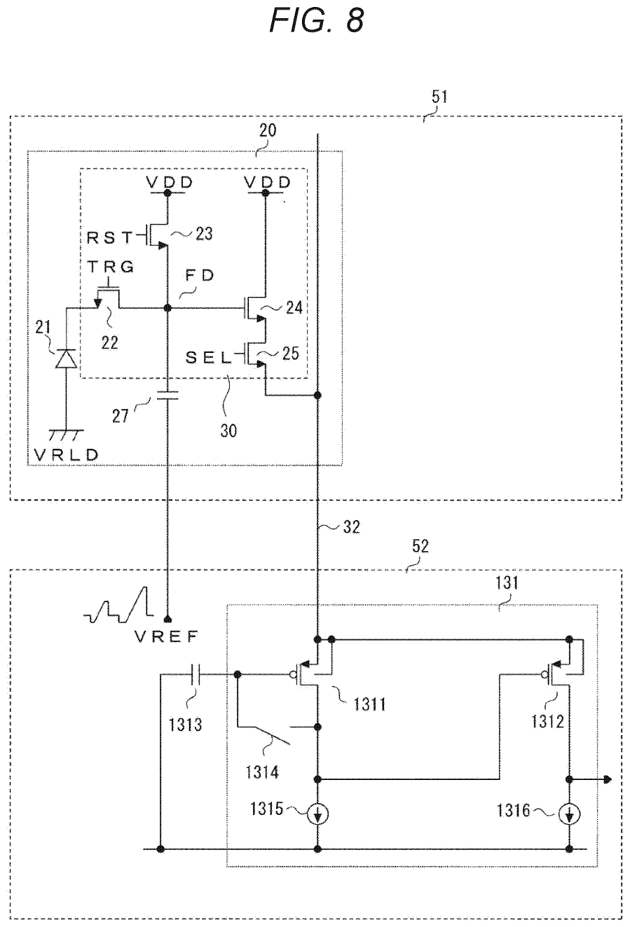

FIG. 8 is a circuit diagram illustrating an example of the comparator 131 and the peripheral portion thereof in the first embodiment of the present disclosure. In the first embodiment of the present disclosure, the pixel 20 includes a capacitor 27. Furthermore, one end of the capacitor 1313 in the comparator 131 is connected to a low-potential-side power supply (for example, ground) that is the reference voltage signal VSTD.

The capacitor 27 is used to change the potential level of the charge-voltage conversion unit FD according to the signal level of the reference signal VREF. The capacitor 27 is inserted between the charge-voltage conversion unit FD and the output node of the reference signal generation unit 16, and is supplied with the reference signal VREF from the reference signal generation unit 16.

The capacitor 1313 is used as an input capacitance for the reference voltage signal VSTD. The capacitor 1313 transmits the reference voltage signal VSTD to the input transistor 1311 in a state of absorbing the offset.

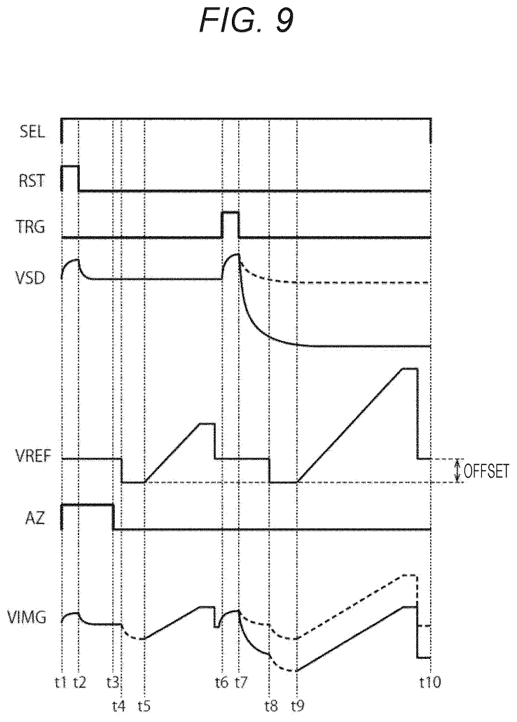

FIG. 9 is a timing chart for explaining operation of the solid-state imaging device 1 in the first embodiment of the present disclosure. The timing chart in FIG. 9 illustrates signal levels of the selection signal SEL for driving the selection transistor 25 in the pixel 20, the reset signal RST for driving the reset transistor 23, and the transfer signal TRG for driving the transfer transistor 22. The timing chart in FIG. 9 further illustrates a pixel signal VSD on the signal line 32 in a case where the capacitor 27 is not provided, the reference signal VREF input to the capacitor 27, an auto-zero signal AZ input to the gate of the auto-zero switch 1314, and the pixel signal VIMG on the signal line 32 in a case where the reference signal VREF is supplied to one end of the capacitor 27.

In the charge-voltage conversion unit FD, when the selection transistor 25 is turned on and the pixel 20 is in a selected state, first, the reset transistor 23 is turned on and the photocharge is reset (from time t1 to time t2). As a result, a potential of the charge-voltage conversion unit FD has the reset level. The reset level is a potential level slightly different for each pixel 20. In parallel, the auto-zero switch 1314 is also turned on in the comparator 131, and the offset adjustment of the input transistor 1311 is performed (from time t1 to time t3).

The charge-voltage conversion unit FD receives supply of the reference signal VREF from the reference signal generation unit 16 in a period from time t1 to time t4. When the reset transistor 23 is turned off at time t2, the charge-voltage conversion unit FD has a potential level in which the signal level of the reference signal VREF is superimposed on the reset level. The reference signal VREF is set to an initial potential (offset potential) within a period from time t4 to time t5. The period is a settling period of the comparator 131 for detecting the reset level of the pixel 20. Thereafter, the signal level of the reference signal VREF changes with time, and accordingly, the signal levels of the charge-voltage conversion unit FD and the pixel signal VIMG on the signal line 32 also change with time. When the signal level of the pixel signal VIMG on the signal line 32 intersects the reference voltage signal VSTD, output logic of the comparator 131 changes. A digital signal corresponding to this timing is the reset level of the pixel 20.

As described above, a period from time t2 to time t6 is a reset level detection period of the pixel 20. On the other hand, a period from time t6 to time t10 is a detection period of the potential level of the pixel signal VIMG based on photoelectric conversion. First, when the transfer transistor 22 is turned on (from time t6 to time t7), charge due to photoelectric conversion from the photoelectric conversion element 21 is transferred to the charge-voltage conversion unit FD. The charge-voltage conversion unit FD has a potential level obtained by superimposing the signal level of the reference signal VREF on a potential level according to the charge due to photoelectric conversion. As a result, the pixel signal VIMG on the signal line 32 has a signal level according to the potential level of the charge-voltage conversion unit FD.

Thereafter, similarly to the reset level detection period, a settling period of the comparator 131 is provided (from time t8 to time t9). During the settling period, the reference signal VREF has the offset potential. After the settling period elapses, the output logic of the comparator 131 changes when the signal level of the pixel signal VIMG intersects the reference voltage signal VSTD again. At time t10, the selection transistor 25 is turned off, and the selected state of the pixel 20 is released.

Signal amplitude of the pixel signal VIMG on the signal line 32 in a case where the capacitor 27 is not provided in the pixel 20 as illustrated in FIG. 5 is larger than signal amplitude of the pixel signal VIMG on the signal line 32 in a case where the capacitor 27 is provided in the pixel 20 and the reference signal VREF is supplied to one end thereof as illustrated in FIG. 8. A broken line in FIG. 9 indicates a signal waveform of the pixel signal VIMG that has received low-luminance light, and a solid line indicates a signal waveform of the pixel signal VIMG that has received high-luminance light. In the solid-state imaging device 1 in FIG. 8, the signal amplitude of the pixel signal VIMG on the signal line 32 can be made smaller than that of the solid-state imaging device 1 in FIG. 5, and a power supply potential level can be lowered accordingly, so that power consumption can be reduced.

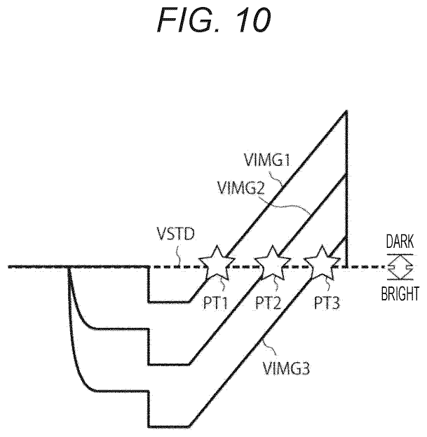

FIG. 10 is a waveform diagram illustrating an input signal input to the comparator 131 in the first embodiment of the present disclosure. Similarly to FIG. 6, FIG. 10 illustrates the pixel signal VIMG1, the pixel signal VIMG2, and the pixel signal VIMG3 in ascending order of the amount of received light of the pixel 20. Furthermore, FIG. 10 illustrates the reference voltage signal VSTD to be compared with the pixel signals VIMG1, VIMG2, and VIMG3, and the timings PT1, PT2, and PT3 at which the pixel signals VIMG1, VIMG2, and VIMG3 intersect with the reference voltage signal VSTD. As illustrated in FIG. 10, since the comparator 131 compares the pixel signal VIMG on the signal line 32 with the reference voltage signal VSTD whose potential level is always fixed, there is no possibility that comparison accuracy varies depending on luminance, and the dynamic range can be expanded.

In the present embodiment, a degree of change of the signal level by the luminance of the pixel signal VIMG is reduced, the pixel signal VIMG is compared with the reference voltage signal VSTD having a fixed potential level by the comparator 131, and a timing at which the pixel signal VIMG intersects the reference voltage signal VSTD is detected. As illustrated in FIG. 8, the input transistor 1311 is connected on the signal line 32 similarly to FIG. 5, but the signal level of the pixel signal VIMG on the signal line 32 connected to the source of the input transistor 1311 is raised by the reference signal VREF, and is not affected by the potential difference between the source and the drain of the input transistor 1311. Thus, there is no possibility that the dynamic range is narrowed by the potential difference between the source and the drain of the input transistor 1311. Furthermore, since a power supply potential of the pixel 20 can be lowered in the solid-state imaging device 1 in FIG. 8, power consumption can be reduced.

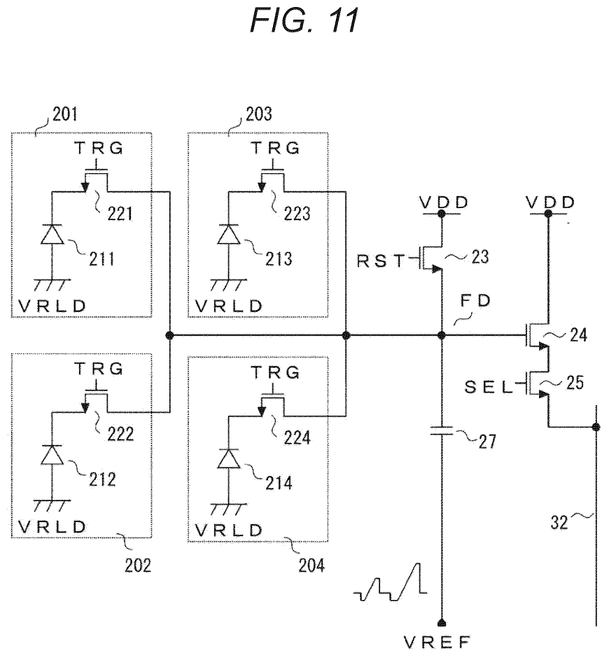

Note that, in the first embodiment of the present disclosure, a part of the pixel circuit 30 may be shared by a plurality of pixels 20. FIG. 11 is a circuit diagram illustrating an example in which a part of the pixel circuit 30 is shared by four pixels 201, 202, 203, and 204. The four pixels 201, 202, 203, and 204 include photoelectric conversion elements 211, 212, 213, and 214, and transfer transistors 221, 222, 223, and 224, respectively. These four pixels 201, 202, 203, and 204 share the charge-voltage conversion unit FD, the capacitor 27, the reset transistor 23, the amplification transistor 24, and the selection transistor 25. The drains of the transfer transistors 221, 222, 223, and 224 in the four pixels 201, 202, 203, and 204 are connected to the charge-voltage conversion unit FD. Charges photoelectrically converted by the four photoelectric conversion elements 21 in the four pixels 201, 202, 203, and 204 are sequentially transferred to the charge-voltage conversion unit FD by sequentially turning on the four transfer transistors 221, 222, 223, and 224, and are superimposed on the signal level of the reference signal VREF.

As illustrated in FIG. 9, the reference signal VREF includes a slope portion in which the potential level linearly changes with time and an offset portion in which the potential level is fixed. The slope portion of the reference signal VREF is used for comparison with the pixel signal VIMG, and the offset portion is used to reliably invert the output of the comparator 131 and ensure linearity of the comparator 131. Since the reference signal VREF in FIG. 9 alternately includes the slope portion and the offset portion, the potential level of the pixel signal VIMG on the signal line 32 changes depending on a potential level of the offset portion. Since a time constant of the signal line 32 is large, when the reference signal VREF is switched from the slope portion to the offset portion, the waveform of the pixel signal VIMG on the signal line 32 is blunted, and it is necessary to secure a long settling time until the waveform is stabilized.

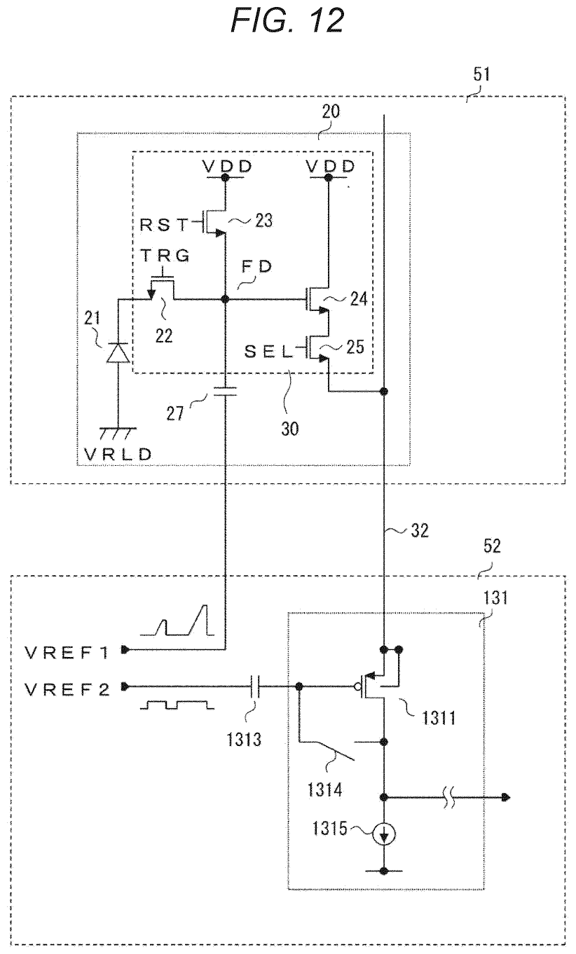

In order to solve such a problem, in the first embodiment of the present disclosure, the slope portion and the offset portion of the reference signal VREF in FIG. 9 may be separated from each other, and the offset portion may be input to the comparator 131, and the slope portion may be used as a reference signal to be input to the pixel 20. Hereinafter, the reference signal VREF including the slope portion is referred to as a first reference signal VREF1, and the reference signal VREF including the offset portion is referred to as a second reference signal VREF2. FIG. 12 is a circuit diagram illustrating an example of the comparator 131 and the peripheral portion thereof in a case where the reference signal VREF is separated into the first reference signal VREF1 and the second reference signal VREF2. The first reference signal VREF1 is supplied to one end of the capacitor 27 in the pixel 20. Since the first reference signal VREF1 has no offset portion, there is no possibility that the waveform of the pixel signal VIMG on the signal line 32 is blunted due to a step of the offset portion. The second reference signal VREF2 is input to one end of the capacitor 27 connected to the gate of the input transistor 1311 in the comparator 131. The second reference signal VREF2 is a signal at a potential level obtained by inverting the offset portion of the original reference signal VREF. A gate voltage of the input transistor 1311 changes according to the potential level of the second reference signal VREF2. Thus, the comparator 131 in FIG. 12 can compare the reference signal VREF including the slope portion and the offset portion with the pixel signal VIMG, similarly to the comparator 131 in FIG. 8.

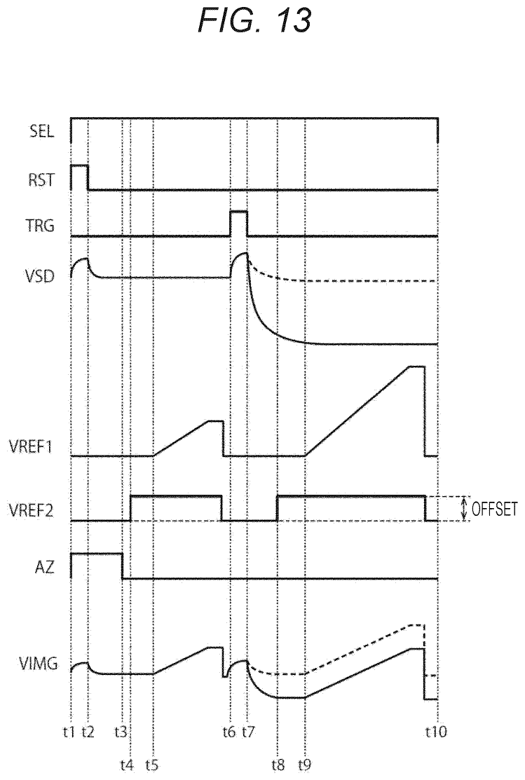

FIG. 13 is an operation timing chart diagram in a case where the reference signal VREF is separated into the first reference signal VREF1 and the second reference signal VREF2 and supplied to each of the pixel 20 and the comparator 131. In this case, the first reference signal VREF1 including the slope portion is superimposed on the pixel signal VIMG, and the offset portion is not superimposed. As a result, the waveform of the pixel signal VIMG on the signal line 32 is not blunted due to influence of the large time constant of the signal line 32, and it is not necessary to wait for settling of the waveform.

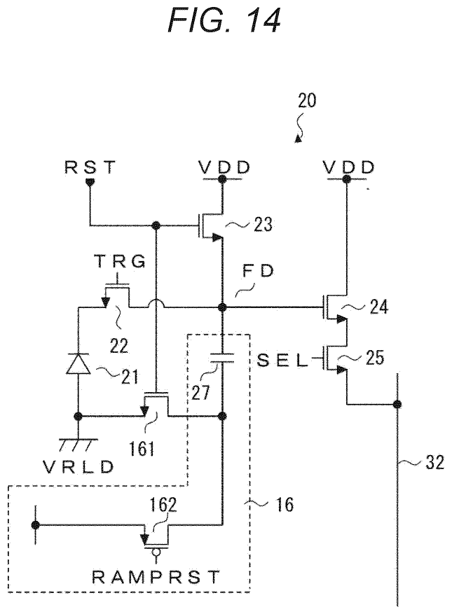

In the first embodiment of the present disclosure, the reference signal generation unit 16 may be provided in the pixel 20. In this case, since it is not necessary to arrange the reference signal generation unit 16 on the circuit chip side, it is possible to reduce the size and power consumption of the circuit chip. FIG. 14 is a circuit diagram of the pixel 20 incorporating the reference signal generation unit 16. The pixel 20 in FIG. 14 includes the reference signal generation unit 16 and a ramp reset transistor 161. The reference signal generation unit 16 in FIG. 14 includes a constant current transistor 162 and the capacitor 27. In this example, a PMOS transistor is used as the constant current transistor 162, and an NMOS transistor is used as the ramp reset transistor 161, but the conductivity type of the transistor is any conductivity type.

The capacitor 27 in the reference signal generation unit 16 functions as a current integration capacitor. In the constant current transistor 162, the source is connected to one end of the capacitor 27, the drain is connected to a constant voltage power supply, and a ramp reset signal RST is input to the gate. During a period in which the ramp reset signal RST is at the low level, the constant current transistor 162 causes a constant current to flow to one end of the capacitor 27. As a result, the potential level of the charge-voltage conversion unit FD rises substantially linearly.

The ramp reset transistor 161 is used to reset the charge accumulated in the capacitor 27 in the pixel 20. In the ramp reset transistor 161, the source is connected to the reference potential node of the photoelectric conversion element 21, the drain is connected to one end of the capacitor 27, and the reset signal RST is input to the gate. During a period in which the reset signal RST is at the high level, a potential level at one end of the capacitor 27 is reset to a level of the reference potential node (for example, a ground voltage node).

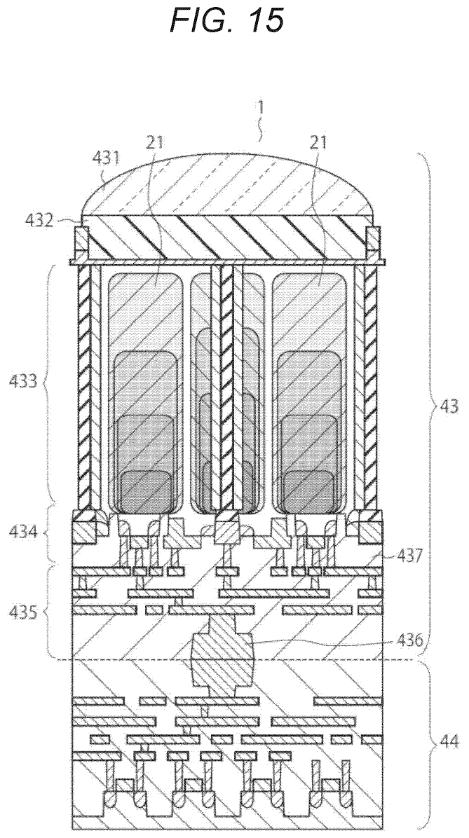

FIG. 15 is a cross-sectional view of the solid-state imaging device 1 of a stacked-type in the first embodiment of the present disclosure. The solid-state imaging device 1 illustrated in FIG. 15 has a structure in which the CIS chip 43 and the logic chip 44 are stacked. The CIS chip 43 is configured by stacking a silicon layer 437 epitaxially grown, a pixel circuit arrangement region 434, and a wiring layer region 435, on a silicon substrate. In the silicon layer 437, a photoelectric conversion layer 433 is provided in which the photoelectric conversion element 21 is arranged. A microlens 431 and a color filter 432 are stacked on the light incident side of the photoelectric conversion layer 433 in the CIS chip 43. The microlens 431 is arranged on the light incident side of the color filter 432.

Light condensed by the microlens 431 is incident on the color filter 432 and separated for each wavelength. Light for each wavelength separated by the color filter 432 is photoelectrically converted by the photoelectric conversion layer 433. The photocharge generated by the photoelectric conversion is transferred to the pixel circuit 30 to generate a voltage signal. A plurality of transistors constituting the pixel circuit 30 has a stacked structure and is arranged in the pixel circuit arrangement region 434. The wiring layer region 435 is arranged between the pixel circuit arrangement region 434 and the logic chip 44, and a plurality of wiring layers connected to the pixel circuit 30 is stacked. The CIS chip 43 and the logic chip 44 are connected together by, for example, Cu—Cu bonding at a connection portion 436, and perform signal transmission.

In the first embodiment of the present disclosure, the capacitor 27 in the pixel 20 illustrated in FIG. 8 is implemented by an interwiring capacitance. Specifically, in a wiring layer film formation process, an electrode connected to the reference signal generation unit 16 and an electrode connected to the charge-voltage conversion unit FD are arranged close to each other with an insulator layer (for example, a silicon oxide film) that insulates wiring layers from each other interposed therebetween. As a result, a metal-oxide-metal (MOM) capacitance is formed by the two electrodes and the insulator layer therebetween, and the MOM capacitance is used as the capacitor 27. The insulator layer arranged around the two electrodes may be an insulating material other than the silicon oxide film, for example, an insulating material such as a silicon nitride film.

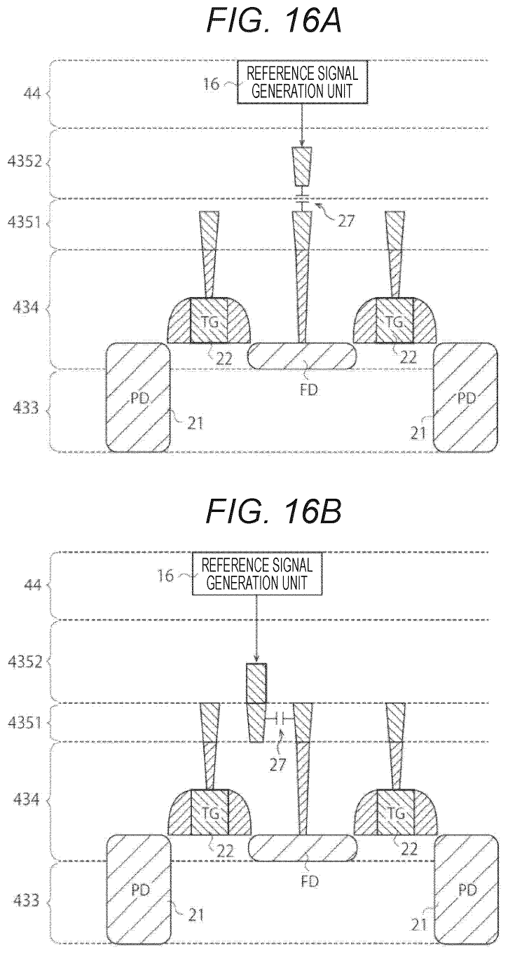

FIGS. 16A and 16B are schematic cross-sectional views illustrating a cross-sectional structure of the capacitor 27 in the pixel 20 illustrated in FIG. 8. Here, the charge-voltage conversion unit FD is arranged in the pixel circuit arrangement region 434, and the reference signal generation unit 16 is arranged on the logic chip 44 side. Furthermore, the capacitor 27 is formed at a boundary surface between an M1 wiring layer 4351 and an M2 wiring layer 4352 in the wiring layer region 435.

Furthermore, in the example in FIG. 16A, among the two electrodes constituting the capacitor 27, the electrode connected to the charge-voltage conversion unit FD is arranged in the M1 wiring layer 4351. On the other hand, the electrode connected to the reference signal generation unit 16 is arranged in the M2 wiring layer 4352. These electrodes are arranged to face each other in a stacking direction. Since the periphery of these electrodes is covered with an insulator layer such as a silicon oxide film, the insulator layer acts as a dielectric, and the capacitor 27 is formed in the stacking direction. On the other hand, FIG. 16B illustrates an example in which the capacitor 27 is formed in a plane direction by two wiring layers having the same height and an insulator layer therebetween. Although FIG. 16B illustrates an example in which the capacitor 27 is formed along the M1 wiring layer 4351, the capacitor 27 may be formed in the plane direction using a wiring layer (for example, the M2 wiring layer 4352) other than the Ml wiring layer 4351. As illustrated in FIGS. 16A and 16B, the capacitor 27 in the pixel 20 illustrated in FIG. 8 can be formed in a process of forming the wiring layer, and it is not necessary to add a new process, so that manufacturing is easy.

As described above, in the first embodiment of the present disclosure, the capacitor 27 is arranged as the interwiring capacitance in the pixel 20, and the signal level of the charge-voltage conversion unit FD is adjusted. Furthermore, in the comparator 131 arranged on the signal line 32, the pixel signal VIMG is compared with a reference signal having a constant signal level. As a result, the signal level of the pixel signal VIMG when the output signal of the comparator 131 is inverted can be made constant regardless of the amount of incident light, and as a result, the dynamic range of the entire solid-state imaging device 1 can be expanded as compared with the basic configuration in FIG. 5.

### Second Embodiment of Present Disclosure

In the first embodiment, the capacitor 27 is formed using an insulator layer that insulates the electrodes from each other in the wiring layer region 435 (for example, the M1 wiring layer 4351 or the M2 wiring layer 4352), whereas in a second embodiment, an insulator layer for the capacitor 27 is provided separately from the insulator layer that insulates the electrodes from each other in the wiring layer.

More specifically, in the second embodiment of the present disclosure, two electrodes and an insulator layer are newly provided in the wiring layer region 435 in FIG. 15 to form the capacitor 27 in the pixel 20. The two electrodes and the insulator layer are inserted between the M1 wiring layer 4351 and the M2 wiring layer 4352, for example, in a wiring process. In the second embodiment of the present disclosure, the capacitor 27 in the pixel 20 includes an electrode connected to the charge-voltage conversion unit FD, an electrode connected to the reference signal generation unit 16, and the insulator layer described above.

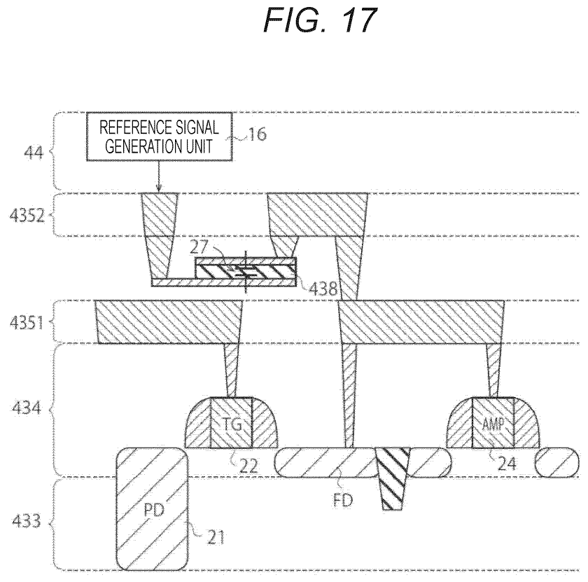

FIG. 17 is a schematic diagram illustrating a cross-sectional structure of the capacitor 27 in the pixel 20 in the second embodiment of the present disclosure. In the second embodiment, for example, an insulator layer 438 is newly provided between the M1 wiring layer 4351 and the M2 wiring layer 4352, and an electrode connected to the reference signal generation unit 16 and an electrode connected to the charge-voltage conversion unit FD are respectively arranged on both sides of the insulator layer 438. As a result, a metal-insulator-metal (MIM) capacitance having two electrodes and the insulator layer 438 is formed in the capacitor 27. Note that, as a material of the insulator layer 438, for example, SiO₂, SiN, Ta₂O₅, ZrO₂, AI₂O₃, or the like is used.

As described above, the second embodiment of the present disclosure requires a process of forming the two electrodes connected to the M1 wiring layer 4351 and the M2 wiring layer 4352, and the insulator layer 438 arranged between these electrodes, as compared with the first embodiment. However, it is easier to form the capacitor 27 having a desired capacitance value than forming the capacitor 27 with the interwiring capacitance as in the first embodiment. Thus, the potential level of the charge-voltage conversion unit FD can be optimized.

### Third Embodiment of Present Disclosure

In the second embodiment described above, an example has been described in which the capacitor 27 having two electrodes and the insulator layer 438 arranged between the electrodes is formed in the CIS chip 43, but the capacitor 27 may be formed in the vicinity of the connection portion 436 between the CIS chip 43 and the logic chip 44.

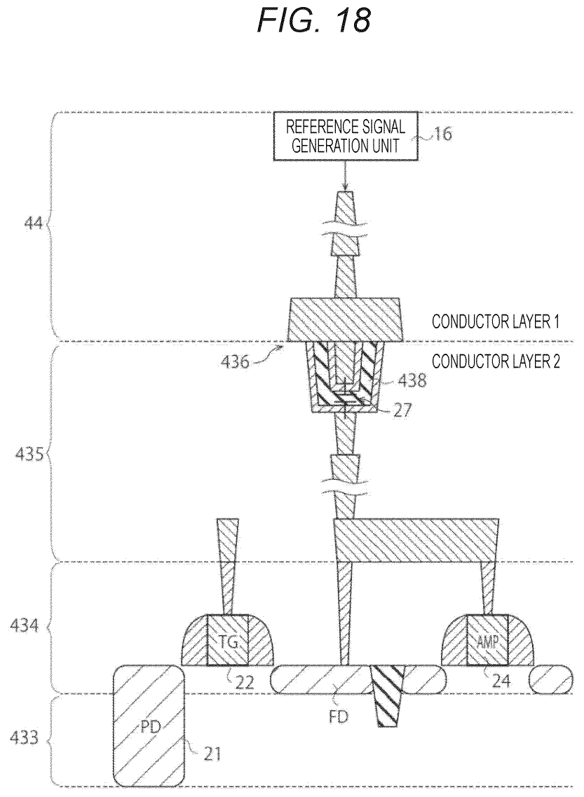

FIG. 18 is a schematic diagram illustrating a cross-sectional structure of the capacitor 27 of the pixel 20 in a third embodiment of the present disclosure. The CIS chip 43 and the logic chip 44 are connected together by the connection portion 436 including Cu—Cu bonding, for example. The Cu—Cu bonding has a structure in which a Cu layer on the CIS chip 43 side and a Cu layer on the logic chip 44 side are directly bonded together. A plurality of Cu—Cu bonding portions is provided on a boundary surface between the CIS chip 43 and the logic chip 44, but there is still a free region on the boundary surface. Thus, in the third embodiment, the capacitor 27 is formed using the free region. As a specific example, two electrodes are formed using a part of the Cu layer on the CIS chip 43 side, and the insulator layer 438 is arranged therebetween. The capacitor 27 including the two electrodes and the insulator layer 438 has the MIM structure described above. The reference signal generation unit 16 is arranged on the logic chip 44 side, and the reference signal VREF is supplied to one electrode on the CIS chip 43 side by Cu—Cu bonding via the Cu layer of the logic chip 44.

Note that the capacitor 27 may be formed in the Cu layer on the logic chip 44 side. Alternatively, one of the two electrodes forming the capacitor 27 may be formed in the Cu layer on the CIS chip 43 side, and the other may be formed in the Cu layer on the logic chip 44 side. In this case, the insulator layer 438 may be provided on the logic chip 44 side, the CIS chip 43 side, or between the logic chip 44 and the CIS chip 43.

As described above, in the third embodiment of the present disclosure, as compared with the second embodiment, the capacitor 27 can be formed in the pixel 20 in a bonding process for the CIS chip 43 and the logic chip 44. Thus, an additional process is not required, and the capacitor 27 can be formed along the Cu—Cu bonding portion, so that it is not necessary to newly secure an arrangement place of the capacitor 27, and the solid-state imaging device 1 can be downsized.

### Fourth Embodiment of Present Disclosure

In the first to third embodiments described above, examples have been described in which the capacitor 27 is formed in the wiring layer region 435 or the connection portion 436, but the capacitor 27 may be formed in the pixel circuit arrangement region 434. For example, in a well region in the silicon layer 437, the capacitor 27 may be formed with a metal-oxide-semiconductor (MOS) capacitance having the same structure as each transistor (hereinafter, may also be referred to as a pixel transistor) constituting the pixel circuit 30. By injecting a high-concentration impurity into a channel region in the well region, it is possible to control a flat band voltage, whereby the capacitor 27 having no voltage dependency can be formed.

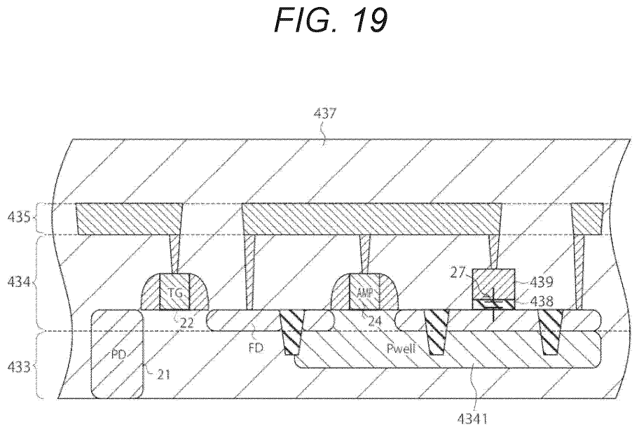

FIG. 19 is a cross-sectional view of the pixel 20 in a fourth embodiment of the present disclosure. As illustrated in FIG. 19, for example, a well region 4341 (P-well region) containing a large amount of p-type impurities is arranged in a part of the silicon layer 437 in which the photoelectric conversion layer 433 is formed. The well region 4341 can be set to any voltage separately from the silicon layer 437. A region under a gate insulating film of the well region 4341 in FIG. 19 is an N+ impurity diffusion region. The N+ impurity diffusion region functions as one electrode of the capacitor 27. The insulator layer 438 is arranged on the well region 4341, and a conductor layer 439 functioning as the other electrode of the capacitor 27 is arranged thereon. The insulator layer 438 and the conductor layer 439 are formed in a process of forming a gate oxide film and a gate electrode of the pixel transistor.

As described above, in the fourth embodiment of the present disclosure, the capacitor 27 including the MOS capacitance having the same structure as the pixel transistor can be formed in a process of forming the pixel transistor. Thus, since the capacitor 27 can be formed in the pixel circuit arrangement region 434 only by adding an injection process, it is not necessary to newly secure an arrangement place of the capacitor 27 in the wiring layer region 435, and the solid-state imaging device 1 can be downsized. Furthermore, by injecting a high-concentration impurity into the channel region of the well region 4341 in the silicon layer 437 in which the capacitor 27 is arranged, it is possible to control the flat band voltage, whereby the MOS capacitance having no voltage dependency can be obtained.

### Fifth Embodiment of Present Disclosure

In the fourth embodiment, the well region 4341 is arranged at the same layer height as the photoelectric conversion element 21, and the capacitor 27 is formed using the well region 4341 as an electrode. On the other hand, in a fifth embodiment, the well region 4341 is arranged in a layer different from a layer in which the photoelectric conversion element 21 is arranged, and the capacitor 27 is formed using the well region 4341 as an electrode.

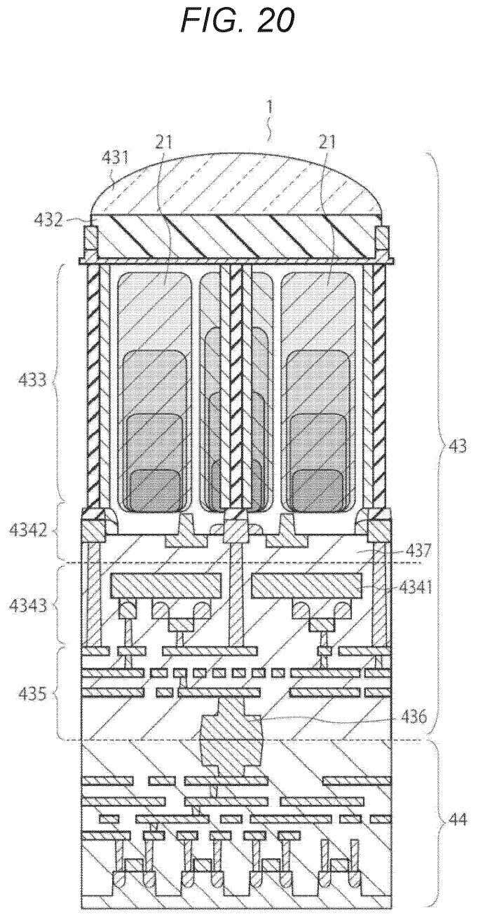

FIG. 20 is a cross-sectional view of the solid-state imaging device 1 of a stacked-type in the fifth embodiment of the present disclosure. The pixel circuit arrangement region 434 in the solid-state imaging device 1 in FIG. 20 has a stacked structure in which a first transistor layer 4342 and a second transistor layer 4343 are stacked. In the first transistor layer 4342, a transfer transistor connected to the photoelectric conversion layer 433 is arranged. In the second transistor layer 4343, pixel transistors other than the transfer transistor are arranged.

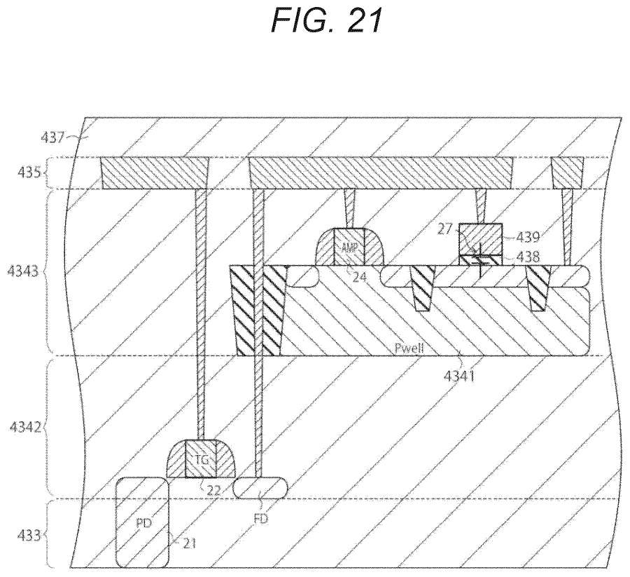

FIG. 21 is a cross-sectional view of the pixel 20 in the fifth embodiment of the present disclosure. FIG. 21 illustrates an example in which the capacitor 27 in the pixel 20 is arranged in the second transistor layer 4343. More specifically, the second transistor layer 4343 is provided with the well region 4341 (P-well region) containing a large amount of p-type impurities, and an N+ impurity diffusion region in the well region 4341 functions as one electrode of the capacitor 27. The insulator layer 438 is arranged on the well region 4341, and a conductor layer 439 functioning as the other electrode of the capacitor 27 is arranged thereon. One electrode, the insulator layer 438, and the other electrode of the capacitor 27 are formed in a process of forming a channel, a gate oxide film, and a gate electrode of a pixel transistor arranged in the second transistor layer 4343. In the example in FIG. 21, the amplification transistor 24 is formed in the second transistor layer 4343 together with the capacitor 27, but the capacitor 27 may be formed alone, or a pixel transistor other than the amplification transistor 24 may be formed.

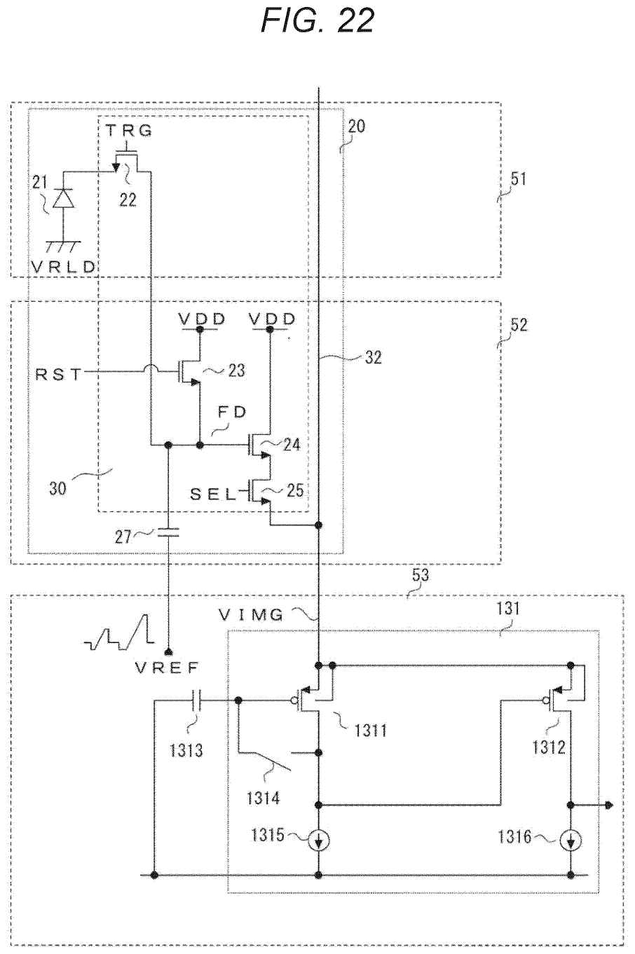

FIG. 22 is a circuit diagram illustrating an example of the comparator 131 and the peripheral portion thereof in the fifth embodiment of the present disclosure. In the fifth embodiment of the present disclosure, the CIS chip 43 includes the first semiconductor layer 51 and the second semiconductor layer 52, and the pixel 20 and the pixel circuit 30 are arranged across the first semiconductor layer 51 and the second semiconductor layer 52. In this example, the photoelectric conversion element 21 and the transfer transistor 22 are arranged in the first semiconductor layer 51, and the other pixel transistors are arranged in the second semiconductor layer 52, but the arrangement of the pixel transistors is not limited to this example. Furthermore, the logic chip 44 includes a third semiconductor layer 53. Similarly to the second semiconductor layer 52 in FIG. 8, the comparator 131 and the like are arranged in the third semiconductor layer 53.

As described above, in the fifth embodiment of the present disclosure, since the capacitor 27 is formed in the pixel circuit arrangement region 434 as in the fourth embodiment, it is possible to downsize the solid-state imaging device 1 only by adding the injection process. Furthermore, by injecting a high-concentration impurity into the channel region of the well region 4341 in the silicon layer 437 in which the capacitor 27 is arranged, it is possible to control the flat band voltage, whereby the MOS capacitance having no voltage dependency can be obtained. Furthermore, since the well region 4341 to be an electrode of the capacitor 27 is arranged in a layer separate from the photoelectric conversion element 21, an area of the capacitor 27 can be further expanded, and a degree of freedom in capacitance of the capacitor 27 is increased.

### Application Example

The technology according to the present disclosure can be applied to various products. For example, the technology according to the present disclosure may also be implemented as a device mounted on any kind of moving body such as an automobile, an electric automobile, a hybrid electric automobile, a motorcycle, a bicycle, a personal mobility, an airplane, a drone, a ship, a robot, a construction machine, or an agricultural machine (tractor).

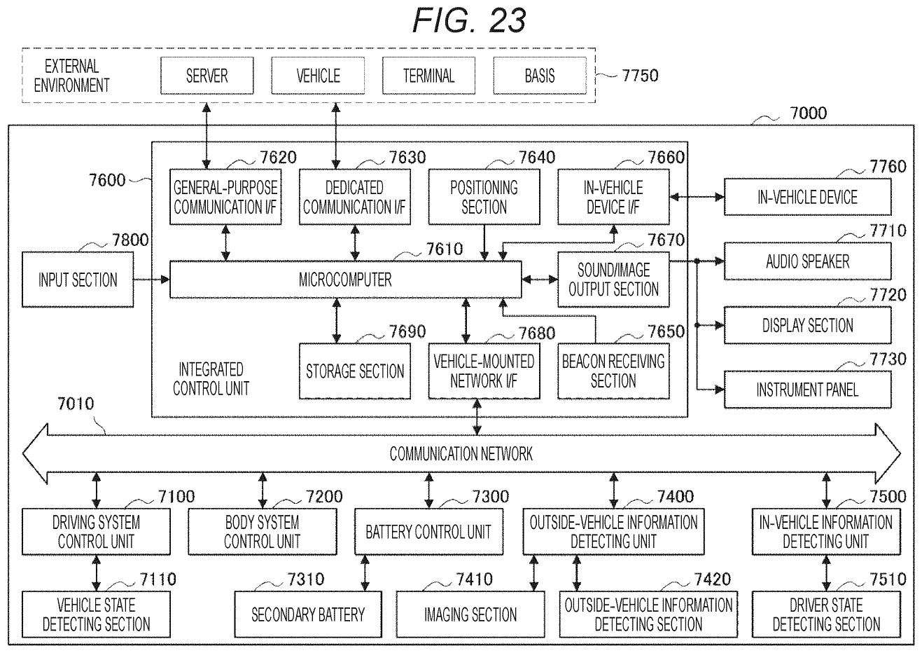

FIG. 23 is a block diagram illustrating a schematic configuration example of a vehicle control system 7000 that is an example of a mobile body control system to which the technology according to the present disclosure may be applied. The vehicle control system 7000 includes a plurality of electronic control units connected to each other via a communication network 7010. In the example illustrated in FIG. 23, the vehicle control system 7000 is provided with a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may be, for example, a vehicle-mounted communication network compliant with any standard such as controller area network (CAN), local interconnect network (LIN), local area network (LAN), or FlexRay (registered trademark).

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like inside and outside a vehicle by wired communication or wireless communication. FIG. 23 illustrates, as a functional configuration of the integrated control unit 7600, a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls operation of devices related to a driving system of a vehicle in accordance with various kinds of programs. For example, the driving system control unit 7100 functions as a control device for a driving force generating device for generating driving force of the vehicle, such as an internal combustion engine or a driving motor, a driving force transmitting mechanism for transmitting the driving force to wheels, a steering mechanism for adjusting a steering angle of the vehicle, a braking device for generating braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects an angular velocity of axial rotational movement of a vehicle body, an acceleration sensor that detects an acceleration of the vehicle, or a sensor for detecting an amount of operation of an accelerator pedal, an amount of operation of a brake pedal, a steering angle of a steering wheel, an engine speed or a rotational speed of wheels, or the like. The driving system control unit 7100 performs arithmetic processing using a signal input from the vehicle state detecting section 7110, and controls the internal combustion engine, the driving motor, an electric power steering device, a brake device, and the like.

The body system control unit 7200 controls operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, and a fog lamp. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, and the like of the vehicle.

The battery control unit 7300 controls a secondary battery 7310, which is a power supply source for the driving motor, in accordance with various kinds of programs. For example, the battery control unit 7300 receives, as an input, information about a battery temperature, a battery output voltage, an amount of charge remaining in the battery, or the like from a battery device including the secondary battery 7310. The battery control unit 7300 performs arithmetic processing using these signals, and performs control for regulating a temperature of the secondary battery 7310, or controls a cooling device provided to the battery device or the like.

The outside-vehicle information detecting unit 7400 detects information about the outside of the vehicle equipped with the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, or another camera. The outside-vehicle information detecting section 7420, for example, includes at least one of an environmental sensor for detecting current atmospheric conditions or weather conditions, or a peripheral information detecting sensor for detecting another vehicle, an obstacle, a pedestrian, or the like on the periphery of the vehicle equipped with the vehicle control system 7000.

The environmental sensor, for example, may be at least one of a rain drop sensor detecting rain, a fog sensor detecting a fog, a sunshine sensor detecting a degree of sunshine, or a snow sensor detecting a snowfall. The peripheral information detecting sensor may be at least one of an ultrasonic sensor, a radar device, or a Light detection and Ranging (LIDAR) device (Laser imaging detection and ranging (LIDAR) device). Each of the imaging section 7410 and the outside-vehicle information detecting section 7420 may be provided as an independent sensor or device, or may be provided as a device in which a plurality of sensors or devices is integrated.

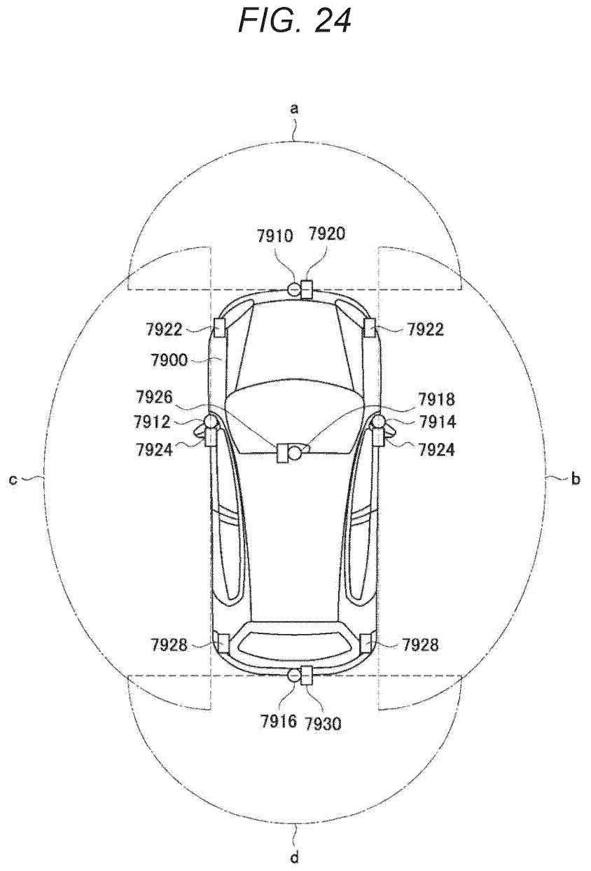

Here, FIG. 24 illustrates an example of installation positions of the imaging section 7410 and the outside-vehicle information detecting section 7420. Imaging sections 7910, 7912, 7914, 7916, and 7918 are, for example, provided at least one of positions on a front nose, sideview mirrors, a rear bumper, and a back door of a vehicle 7900 and an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Note that, FIG. 24 illustrates an example of imaging ranges of the imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose, the rear bumper, and the back door of the vehicle 7900 and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 23, the description is continued. The outside-vehicle information detecting unit 7400 causes the imaging section 7410 image an image of the outside of the vehicle, and receives imaged image data. Furthermore, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information on a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

Furthermore, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may perform processing such as distortion correction, alignment, or the like on the received image data, and combine the image data imaged by different imaging sections 7410 to generate a bird's-eye image or a panoramic image. The outside-vehicle information detecting unit 7400 may perform viewpoint conversion processing using the image data imaged by the different imaging sections 7410.

The in-vehicle information detecting unit 7500 detects information about the inside of the vehicle. The in-vehicle information detecting unit 7500 is, for example, connected with a driver state detecting section 7510 that detects a state of a driver. The driver state detecting section 7510 may include a camera that images the driver, a biosensor that detects biological information on the driver, a microphone that collects sound within the interior of the vehicle, or the like. The biosensor is, for example, provided in a seat surface, the steering wheel, or the like, and detects biological information on an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may perform processing such as noise canceling processing or the like on an audio signal collected.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, for example, a touch panel, a button, a microphone, a switch, a lever, or the like. The integrated control unit 7600 may receive, as an input, data obtained by voice recognition of voice input through the microphone. The input section 7800 may be, for example, a remote control device using infrared rays or other radio waves, or an external connecting device such as a mobile phone or a personal digital assistant (PDA) that supports operation of the vehicle control system 7000. The input section 7800 may be, for example, a camera. In that case, the occupant can input information by gesture. Alternatively, data may be input that is obtained by detecting the movement of a wearable device worn by the occupant. Moreover, the input section 7800 may include, for example, an input control circuit or the like that generates an input signal on the basis of information input by the occupant or the like using the input section 7800 described above and outputs the generated input signal to the integrated control unit 7600. The occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. Furthermore, the storage section 7690 may be implemented by a magnetic storage device such as a hard disc drive (HDD), a semiconductor storage device, an optical storage device, a magneto-optical storage device, or the like.

The general-purpose communication I/F 7620 is a general purpose communication I/F that mediates communication with various devices present in an external environment 7750. The general-purpose communication I/F 7620 may implement a cellular communication protocol such as global system of mobile communications (GSM (registered trademark)), worldwide interoperability for microwave access (WiMAX (registered trademark)), long term evolution (LTE (registered trademark)), or LTE-advanced (LTE-A), or another wireless communication protocol such as wireless LAN (referred to also as wireless fidelity (Wi-Fi (registered trademark)), or Bluetooth (registered trademark). The general-purpose communication I/F 7620 may, for example, connect to a device (for example, an application server or a control server) present on an external network (for example, the Internet, a cloud network, or a company-specific network) via a base station or an access point. Furthermore, the general-purpose communication I/F 7620 may connect to a terminal (for example, a terminal of the driver, a pedestrian, or a store, or a machine type communication (MTC) terminal) present in the vicinity of the vehicle by using a peer to peer (P2P) technology, for example.

The dedicated communication I/F 7630 is a communication I/F that supports a communication protocol developed for use in vehicles. The dedicated communication I/F 7630 may implement a standard protocol, for example, wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a global positioning system (GPS) signal from a GPS satellite), and generates positional information including the latitude, longitude, and altitude of the vehicle. Note that, the positioning section 7640 may identify a current position by exchanging signals with a wireless access point, or may obtain the positional information from a terminal such as a mobile phone, a personal handyphone system (PHS), or a smart phone that has a positioning function.

The beacon receiving section 7650, for example, receives a radio wave or an electromagnetic wave transmitted from a wireless station or the like installed on a road, and obtains information about the current position, congestion, a closed road, a necessary time, or the like. Note that, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present inside the vehicle. The in-vehicle device I/F 7660 may establish wireless connection using a wireless communication protocol such as wireless LAN, Bluetooth (registered trademark), near field communication (NFC), or wireless universal serial bus (WUSB). Furthermore, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not illustrated in the figure. The in-vehicle devices 7760 may include, for example, at least one of a mobile device and a wearable device possessed by an occupant and an information device carried into or attached to the vehicle. The in-vehicle devices 7760 may also include a navigation device that searches for a path to any destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, or the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS), the functions including collision avoidance or shock mitigation for the vehicle, following driving based on a following distance, vehicle speed maintaining driving, a warning of collision of the vehicle, a warning of deviation of the vehicle from a lane, or the like. Furthermore, the microcomputer 7610 may perform cooperative control intended for automated driving, which makes the vehicle to travel autonomously without depending on the driver's operation, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure or a person, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, or the vehicle-mounted network I/F 7680. Furthermore, the microcomputer 7610 may predict danger such as collision of the vehicle, approaching of a pedestrian or the like, an entry to a closed road, or the like on the basis of the obtained information, and generate a warning signal. The warning signal may be, for example, a signal for producing a warning sound or lighting a warning lamp.

The sound/image output section 7670 transmits an output signal of at least one of a sound or an image to an output device capable of visually or auditorily performing notification of information to an occupant of the vehicle or the outside of the vehicle. In the example in FIG. 23, as the output device, an audio speaker 7710, a display section 7720, and an instrument panel 7730 are illustrated. The display section 7720 may include, for example, at least one of an on-board display or a head-up display. The display section 7720 may have an augmented reality (AR) display function. The output device may be other than these devices, and may be another device such as headphones, a wearable device such as an eyeglass type display worn by an occupant, a projector, or a lamp. In a case where the output device is a display device, the display device visually displays results obtained by various kinds of processing performed by the microcomputer 7610 or information received from another control unit in various forms such as text, an image, a table, and a graph. Furthermore, in a case where the output device is an audio output device, the audio output device converts an audio signal including reproduced audio data, sound data, or the like into an analog signal, and auditorily outputs the analog signal.

Note that, in the example illustrated in FIG. 23, at least two control units connected via the communication network 7010 may be integrated as one control unit. Alternatively, each individual control unit may include a plurality of control units. Moreover, the vehicle control system 7000 may include another control unit not illustrated in the figure. Furthermore, some or all of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that the present technology may have the following configurations.
(1) A solid-state imaging device including: a photoelectric conversion element; a charge-voltage conversion unit that converts charge photoelectrically converted by the photoelectric conversion element into a voltage; a capacitor that is connected to the charge-voltage conversion unit and adjusts a voltage level of the charge-voltage conversion unit; a first semiconductor layer in which at least one of the photoelectric conversion element or the capacitor is arranged; a signal line that transmits a pixel signal according to the voltage level of the charge-voltage conversion unit; and a comparator that is arranged on the signal line and compares the pixel signal with a predetermined reference signal.
(2) The solid-state imaging device according to (1), further including a reference signal generation unit that generates a reference signal whose voltage level is changeable with time, in which the capacitor adjusts the voltage level of the charge-voltage conversion unit on the basis of the reference signal.
(3) The solid-state imaging device according to (1), further including a switching element that is connected to the capacitor and increases or decreases a voltage level of the capacitor while the switching element continues to be turned on or off.
(4) The solid-state imaging device according to (2), in which the capacitor includes a first electrode connected to the charge-voltage conversion unit, a second electrode to which the reference signal is applied, and an insulator layer arranged between the first electrode and the second electrode.
(5) The solid-state imaging device according to (4), in which the first electrode and the second electrode are arranged to be separated from each other in a plane direction of a wiring layer connected to the charge-voltage conversion unit.
(6) The solid-state imaging device according to (4), in which the first electrode and the second electrode are arranged to be separated from each other in a stacking direction of a wiring layer connected to the charge-voltage conversion unit.
(7) The solid-state imaging device according to any one of (1) to (3), further including: a first wiring layer and a second wiring layer stacked on the first semiconductor layer; and an insulator layer arranged between the first wiring layer and the second wiring layer, in which the capacitor includes the first wiring layer, the second wiring layer, and the insulator layer.
(8) The solid-state imaging device according to any one of (1) to (7), in which pixels including the photoelectric conversion element, the capacitor, and a pixel circuit are arranged in the first semiconductor layer.
(9) The solid-state imaging device according to (8), in which the capacitor and the charge-voltage conversion unit are provided for each of the pixels.
(10) The solid-state imaging device according to (8), in which the capacitor and the charge-voltage conversion unit are shared by a plurality of the pixels.
(11) The solid-state imaging device according to any one of (1) to (10), further including: a first chip including the first semiconductor layer; and a second chip stacked on the first chip and including a second semiconductor layer, in which the comparator is provided in the second semiconductor layer.
(12) The solid-state imaging device according to any one of (1) to (10), further including: a first chip including the first semiconductor layer; and a second chip stacked on the first chip and including a second semiconductor layer, in which the comparator is provided in the second semiconductor layer, and the capacitor is arranged at a bonding portion between the first chip and the second chip.
(13) The solid-state imaging device according to (12), in which the bonding portion includes: a first conductive layer; a second conductive layer; and an insulator layer arranged between the first conductive layer and the second conductive layer.
(14) The solid-state imaging device according to (13), in which the first conductive layer, the insulator layer, and the second conductive layer are arranged along a stacking direction of the first chip and the second chip.
(15) The solid-state imaging device according to any one of (1) to (3), further including a pixel circuit including at least one transistor that performs control to read out charge photoelectrically converted by the photoelectric conversion element, in which the capacitor includes: a first electrode arranged at a layer height identical to a layer height of a gate electrode of the transistor; a second electrode arranged at a layer height identical to a layer height of a source region and a drain region of the transistor; and an insulator layer arranged at a layer height identical to a layer height of a gate insulating film of the transistor.
(16) The solid-state imaging device according to any one of (1) to (3), further including a second semiconductor layer that is stacked on the first semiconductor layer and in which the capacitor and at least one transistor that performs control to read out charge photoelectrically converted by the photoelectric conversion element are arranged, in which the capacitor includes: a first electrode arranged at a layer height identical to a layer height of a gate electrode of the transistor; a second electrode arranged at a layer height identical to a layer height of a source region and a drain region of the transistor; and an insulator layer arranged at a layer height identical to a layer height of a gate insulating film of the transistor.
(17) The solid-state imaging device according to (15) or (16), further including
a well region in which at least a part of the capacitor is arranged, in which
a flat band voltage is controlled by adjusting an amount of impurities of at least a part in the well region.
(18) The solid-state imaging device according to (15) or (16), further including: a first chip including the first semiconductor layer; and a second chip stacked on the first chip and including a third semiconductor layer, in which the comparator is provided in the third semiconductor layer.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions can be made without departing from the conceptual idea and gist of the present disclosure derived from the contents defined in the claims and equivalents and the like thereof.

### REFERENCE SIGNS LIST

1 Solid-state imaging device
11 Pixel array unit
12 Row selection unit
13 Analog-digital conversion unit
14 Logic circuit unit
15 Timing control unit
16 Reference signal generation unit
20, 201, 202, 203, 204 Pixel
21, 211, 212, 213, 214 Photoelectric conversion element
22, 221, 222, 223, 224 Transfer transistor
23 Reset transistor
24 Amplification transistor
25 Selection transistor
27, 1313 Capacitor
30 Pixel circuit
31 Row selection line
32 Signal line
41 Semiconductor chip
42 Pad
43 CIS chip
44 Logic chip
51 First semiconductor layer
52 Second semiconductor layer
53 Third semiconductor layer
130 Analog-digital converter
131 Comparator
132 Counter
161 Ramp reset transistor
162 Constant current transistor
431 Microlens
432 Color filter
433 Photoelectric conversion layer
434 Pixel circuit arrangement region
435 Wiring layer region
436 Connection portion
437 Silicon layer
438 Insulator layer
439 Conductor layer
1311 Input transistor
1312 Output transistor
1314 Auto-zero switch
1315 Input-side load current source
1316 Output-side load current source
4341 Well region
4342 First transistor layer
4343 Second transistor layer
4351, 4352 Wiring layer

1. A solid-state imaging device comprising:
a photoelectric conversion element;
a charge-voltage conversion unit that converts charge photoelectrically converted by the photoelectric conversion element into a voltage;
a capacitor that is connected to the charge-voltage conversion unit and adjusts a voltage level of the charge-voltage conversion unit;
a first semiconductor layer in which at least one of the photoelectric conversion element or the capacitor is arranged;
a signal line that transmits a pixel signal according to the voltage level of the charge-voltage conversion unit; and
a comparator that is arranged on the signal line and compares the pixel signal with a predetermined reference signal.

2. The solid-state imaging device according to claim 1, further comprising
a reference signal generation unit that generates a reference signal whose voltage level is changeable with time, wherein
the capacitor adjusts the voltage level of the charge-voltage conversion unit on a basis of the reference signal.

3. The solid-state imaging device according to claim 1, further comprising a switching element that is connected to the capacitor and increases or decreases a voltage level of the capacitor while the switching element continues to be turned on or off.

4. The solid-state imaging device according to claim 2, wherein the capacitor includes a first electrode connected to the charge-voltage conversion unit, a second electrode to which the reference signal is applied, and an insulator layer arranged between the first electrode and the second electrode.

5. The solid-state imaging device according to claim 4, wherein the first electrode and the second electrode are arranged to be separated from each other in a plane direction of a wiring layer connected to the charge-voltage conversion unit.

6. The solid-state imaging device according to claim 4, wherein the first electrode and the second electrode are arranged to be separated from each other in a stacking direction of a wiring layer connected to the charge-voltage conversion unit.

7. The solid-state imaging device according to claim 1, further comprising:
a first wiring layer and a second wiring layer stacked on the first semiconductor layer; and
an insulator layer arranged between the first wiring layer and the second wiring layer, wherein
the capacitor includes the first wiring layer, the second wiring layer, and the insulator layer.

8. The solid-state imaging device according to claim 1, wherein pixels including the photoelectric conversion element, the capacitor, and a pixel circuit are arranged in the first semiconductor layer.

9. The solid-state imaging device according to claim 8, wherein the capacitor and the charge-voltage conversion unit are provided for each of the pixels.

10. The solid-state imaging device according to claim 8, wherein the capacitor and the charge-voltage conversion unit are shared by a plurality of the pixels.

11. The solid-state imaging device according to claim 1, further comprising:
a first chip including the first semiconductor layer; and
a second chip stacked on the first chip and including a second semiconductor layer, wherein
the comparator is provided in the second semiconductor layer.

12. The solid-state imaging device according to claim 1, further comprising:
a first chip including the first semiconductor layer; and
a second chip stacked on the first chip and including a second semiconductor layer, wherein
the comparator is provided in the second semiconductor layer, and
the capacitor is arranged at a bonding portion between the first chip and the second chip.

13. The solid-state imaging device according to claim 12, wherein
the bonding portion includes:
a first conductive layer;
a second conductive layer; and
an insulator layer arranged between the first conductive layer and the second conductive layer.

14. The solid-state imaging device according to claim 13, wherein the first conductive layer, the insulator layer, and the second conductive layer are arranged along a stacking direction of the first chip and the second chip.

15. The solid-state imaging device according to claim 1, further comprising
a pixel circuit including at least one transistor that performs control to read out charge photoelectrically converted by the photoelectric conversion element, wherein
the capacitor includes:
a first electrode arranged at a layer height identical to a layer height of a gate electrode of the transistor;
a second electrode arranged at a layer height identical to a layer height of a source region and a drain region of the transistor; and
an insulator layer arranged at a layer height identical to a layer height of a gate insulating film of the transistor.

16. The solid-state imaging device according to claim 1, further comprising
a second semiconductor layer that is stacked on the first semiconductor layer and in which the capacitor and at least one transistor that performs control to read out charge photoelectrically converted by the photoelectric conversion element are arranged, wherein
the capacitor includes:
a first electrode arranged at a layer height identical to a layer height of a gate electrode of the transistor;
a second electrode arranged at a layer height identical to a layer height of a source region and a drain region of the transistor; and
an insulator layer arranged at a layer height identical to a layer height of a gate insulating film of the transistor.

17. The solid-state imaging device according to claim 15, further comprising
a well region in which at least a part of the capacitor is arranged, wherein
a flat band voltage is controlled by adjusting an amount of impurities of at least a part in the well region.

18. The solid-state imaging device according to claim 15, further comprising:
a first chip including the first semiconductor layer; and
a second chip stacked on the first chip and including a third semiconductor layer, wherein
the comparator is provided in the third semiconductor layer.
